(19) United States
(12) Patent Application Publication
(10) Pub. No.: US 2018/0061779 A1
(43) Pub. Date: Mar. 1, 2018

(54) SEMICONDUCTOR DEVICE

(71) Applicant: OLYMPUS CORPORATION, Tokyo (JP)

(72) Inventors: Naohiro Takazawa, Tokyo (JP); Yoshitaka Tadaki, Hanno-shi (JP)

(73) Assignee: OLYMPUS CORPORATION, Tokyo (JP)

(21) Appl. No.: 15/801,588

(22) Filed: Nov. 2, 2017

Related U.S. Application Data
(63) Continuation of application No. PCT/JP2015/068836, filed on Jun. 30, 2015.

(51) Int. Cl. H01L 23/00; H01L 23/48; H01L 23/522

(52) U.S. Cl. CPC H01L 23/564; H01L 24/17; H01L 2224/0401; H01L 23/5226; H01L 24/06; H01L 23/481

(57) ABSTRACT

A semiconductor device includes a first substrate, a second substrate, a first pad, a second pad, a first micro-bump, a first resin layer, and an insulating layer. The first substrate has a first semiconductor layer and a first wire layer. The second substrate has a second semiconductor layer and a second wire layer. The insulating layer contains an insulating material having hygroscopic properties lower than hygroscopic properties of the first resin layer. The insulating layer penetrates the second substrate and the first resin layer. The insulating layer surrounds the first micro-bump in a first cross section which passes through the first micro-bump, the first resin layer, and the insulating layer and is parallel to the first surface.

This application is a continuation application based on International Patent Application No. PCT/JP2015/068836, filed on Jun. 30, 2015, the contents of which are incorporated herein by reference.

### BACKGROUND OF THE INVENTION

### Field of the Invention

The present invention relates to a semiconductor device.

### Description of Related Art

Japanese Unexamined Patent Application, First Publication No. 2012-256737 discloses a semiconductor device having a plurality of stacked substrates. FIG. 20 shows a configuration of a semiconductor device 1010 having a plurality of substrates. In FIG. 20, a cross section of the semiconductor device 1010 is shown. As shown in FIG. 20, the semiconductor device 1010 has a first substrate 1100, a second substrate 1200, and a connection portion 1300. The first substrate 1100 and the second substrate 1200 are connected to each other via the connection portion 1300. The first substrate 1100 and the second substrate 1200 are stacked in a thickness direction Dr1001 of the first substrate 1100.

The first substrate 1100 has a first semiconductor layer 1110 and a first wire layer 1120. The first semiconductor layer 1110 and the first wire layer 1120 are stacked in the thickness direction Dr1001 of the first substrate 1100. In addition, the first semiconductor layer 1110 and the first wire layer 1120 are in contact with each other.

The first wire layer 1120 has first wires 1121, first vias 1122, and a first interlayer insulating film 1123. In FIG. 20, there are a plurality of first wires 1121, but the reference numeral is indicated for one first wire 1121 representatively. In FIG. 20, there are a plurality of first vias 1122, but the reference numeral is indicated for one first via 1122 representatively.

Each of the first wires 1121 is a thin film in which a wire pattern is formed. The first wires 1121 transmit signals. In the example shown in FIG. 20, two layers of the first wires 1121 are formed. The first vias 1122 connect two different layers of the first wires 1121. In the first wire layer 1120, portions other than the first wires 1121 and the first vias 1122 are formed by the first interlayer insulating film 1123.

The second substrate 1200 has a second semiconductor layer 1210 and a second wire layer 1220. The second semiconductor layer 1210 and the second wire layer 1220 are stacked in the thickness direction Dr1001. In addition, the second semiconductor layer 1210 and the second wire layer 1220 are in contact with each other.

The second wire layer 1220 has second wires 1221, second vias 1222, and a second interlayer insulating film 1223. In FIG. 20, there are a plurality of second wires 1221, but the reference numeral is indicated for one second wire 1221 representatively. In FIG. 20, there are a plurality of second vias 1222, but the reference numeral is indicated for one second via 1222 representatively.

Each of the second wires 1221 is a thin film in which a wire pattern is formed. The second wires 1221 transmit signals. In the example shown in FIG. 20, two layers of the second wires 1221 are formed. The second vias 1222 connect two different layers of the second wires 1221. In the second wire layer 1220, portions other than the second wires 1221 and the second vias 1222 are formed by the second interlayer insulating film 1223.

The first substrate 1100 and the second substrate 1200 are disposed such that the first wire layer 1120 and the second wire layer 1220 face each other.

The connection portions 1300 are disposed between the first wire layer 1120 and the second wire layer 1220. The connection portion 1300 electrically connects the first wires 1121 and the second wires 1221 with each other. The connection portion 1300 has a first pad 1301, a second pad 1302, a micro-bump 1303, and a resin layer 1304. In FIG. 20, there are a plurality of first pads 1301, but the reference numeral is indicated for one first pad 1301 representatively. In FIG. 20, there are a plurality of second pads 1302, but the reference numeral is indicated for one second pad 1302 representatively. In FIG. 20, there are a plurality of micro-bumps 1303, but the reference numeral is indicated for one micro-bump 1303 representatively.

The first pads 1301 are thin films. The first pads 1301 are disposed on the outer surface of the first wire layer 1120. The first pads 1301 are in contact with the first vias 1122 on the outer surface of the first wire layer 1120. Therefore, the first pads 1301 are electrically connected to the first wires 1121.

The second pads 1302 are thin films. The second pads 1302 are disposed on the outer surface of the second wire layer 1220. The second pads 1302 are in contact with the second vias 1222 on the outer surface of the second wire layer 1220. Therefore, the second pads 1302 are electrically connected to the second wires 1221.

The micro-bumps 1303 are columnar structures. The micro-bumps 1303 are disposed between the first pads 1301 and the second pads 1302 and are electrically connected to the first pads 1301 and the second pads 1302. Due to the configuration described above, the first pads 1301, the second pads 1302, and the micro-bumps 1303 are electrically connected to the first wires 1121 and the second wires 1221 and transmit signals between the first substrate 1100 and the second substrate 1200.

The resin layer 1304 is disposed between the first wire layer 1120 and the second wire layer 1220. For example, the resin layer 1304 is constituted of underfill resin. The resin layer 1304 covers the outer surfaces of the first pads 1301, the second pads 1302, and the micro-bumps 1303.

When the resin layer 1304 is not provided, the first substrate 1100 and the second substrate 1200 are connected to each other through only the first pads 1301, the second pads 1302, and the micro-bumps 1303. In this case, the joining strength between the first substrate 1100 and the second substrate 1200 is insufficient. The joining strength between the first substrate 1100 and the second substrate 1200 increases when the resin layer 1304 is provided.

### SUMMARY OF THE INVENTION

According to a first aspect of the present invention, a semiconductor device includes a first substrate, a second substrate, a first pad, a second pad, a first micro-bump, a first resin layer, and an insulating layer. The first substrate has a first semiconductor layer and a first wire layer. The first semiconductor layer has a first surface and a second surface and contains a first semiconductor material. The first wire layer has a third surface, a fourth surface, and a first wire. The third surface faces the second surface. The second substrate has a second semiconductor layer and a second wire layer. The second semiconductor layer has a fifth surface and a sixth surface and contains a second semiconductor material. The second wire layer has a seventh surface, an eighth surface, and a second wire. The seventh surface faces the sixth surface. The first pad is disposed on the first surface or the fourth surface and is electrically connected to the first wire. The second pad is disposed on the fifth surface or the eighth surface and is electrically connected to the second wire. The first micro-bump is disposed between the first substrate and the second substrate and is electrically connected to the first pad and the second pad. The first resin layer is disposed between the first substrate and the second substrate, is in contact with the first pad, the second pad, and the first micro-bump, and contains a first resin material. The insulating layer contains an insulating material having hygroscopic properties lower than hygroscopic properties of the first resin layer. The insulating layer penetrates the second substrate and the first resin layer. The insulating layer surrounds the first micro-bump in a first cross section which passes through the first micro-bump, the first resin layer, and the insulating layer and is parallel to the first surface.

According to a second aspect of the present invention, in the first aspect, the first substrate may have a groove. The groove may be open on the first surface when the first pad is disposed on the first surface. The groove may be open on the fourth surface when the first pad is disposed on the fourth surface. The insulating layer may also be disposed in the groove.

According to a third aspect of the present invention, in the first aspect, the semiconductor device may further include a metal layer that contains a metal material. The metal layer may penetrate the second substrate and may be disposed inside the first resin layer. The metal layer may surround the first micro-bump in the first cross section. The insulating layer may surround the metal layer in the first cross section.

According to a fourth aspect of the present invention, in the first aspect, the insulating layer may include an end portion of the semiconductor device.

According to a fifth aspect of the present invention, in the first aspect, the second pad may be disposed on the eighth surface.

According to a sixth aspect on the present invention, in the first aspect, the second semiconductor layer may have a through-via which penetrates the second semiconductor layer. The second pad may be disposed on the fifth surface and may be electrically connected to the second wire by the through-via.

According to a seventh aspect of the present invention, in the first aspect, the semiconductor device may further include a third substrate, a third pad, a fourth pad, a second micro-bump, and a second resin layer. The third substrate may have a third semiconductor layer and a third wire layer. The third semiconductor layer may have a ninth surface and a tenth surface and may contain a third semiconductor material. The third wire layer may have an eleventh surface, a twelfth surface, and a third wire. The eleventh surface may face the tenth surface. The third pad may be disposed on the eighth surface or the fifth surface and may be electrically connected to the second wire. The fourth pad may be disposed on the ninth surface or the twelfth surface and may be electrically connected to the third wire. The second micro-bump may be disposed between the second substrate and the third substrate and may be electrically connected to the third pad and the fourth pad. The second resin layer may be disposed between the second substrate and the third substrate, may be in contact with the third pad, the fourth pad, and the second micro-bump, and may contain a second resin material. The insulating layer may contain an insulating material having hygroscopic properties lower than hygroscopic properties of both of the first resin layer and the second resin layer. The insulating layer may also penetrate the third substrate. The insulating layer may surround the second micro-bump in a second cross section which passes through the second micro-bump, the second resin layer, and the insulating layer and is parallel to the first surface.

### BRIEF DESCRIPTION OF THE DRAWINGS

FIG. 1 is a cross-sectional view of a semiconductor device according to a first embodiment of the present invention.

FIG. 2 is a cross-sectional view of the semiconductor device according to the first embodiment of the present invention.

FIG. 3 is a cross-sectional view of the semiconductor device according to the first embodiment of the present invention.

FIG. 4 is a cross-sectional view of a semiconductor device according to a second embodiment of the present invention.

FIG. 5 is a cross-sectional view of the semiconductor device according to the second embodiment of the present invention.

FIG. 6 is a cross-sectional view of a semiconductor device according to a third embodiment of the present invention.

FIG. 7 is a cross-sectional view of the semiconductor device according to the third embodiment of the present invention.

FIG. 8 is a cross-sectional view of a semiconductor device according to a fourth embodiment of the present invention.

FIG. 9 is a cross-sectional view of the semiconductor device according to the fourth embodiment of the present invention.

FIG. 10 is a cross-sectional view of the semiconductor device according to the fourth embodiment of the present invention.

FIG. 11 is a cross-sectional view of a semiconductor device according to a fifth embodiment of the present invention.

FIG. 12 is a cross-sectional view of a semiconductor device according to a sixth embodiment of the present invention.

FIG. 13 is a cross-sectional view of a semiconductor device according to a seventh embodiment of the present invention.

FIG. 14 is a cross-sectional view of a semiconductor device according to an eighth embodiment of the present invention.

FIG. 15 is a cross-sectional view of a semiconductor device according to a ninth embodiment of the present invention.

FIG. 16 is a cross-sectional view of a semiconductor device according to a tenth embodiment of the present invention.

FIG. 17 is a cross-sectional view of the semiconductor device according to the tenth embodiment of the present invention.

FIG. 18 is a cross-sectional view of the semiconductor device according to the tenth embodiment of the present invention.

FIG. 19 is a cross-sectional view of a semiconductor device according to an eleventh embodiment of the present invention.

FIG. 20 is a cross-sectional view of a semiconductor device in the related art.

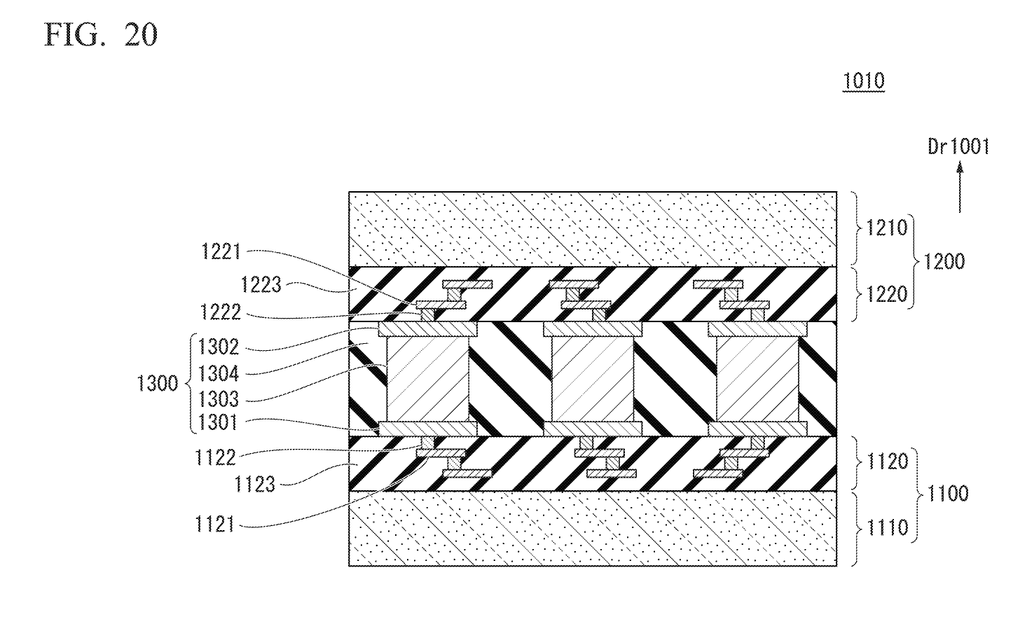

### DETAILED DESCRIPTION OF THE INVENTION

Embodiments of the present invention will be described with reference to the drawings.

### First Embodiment

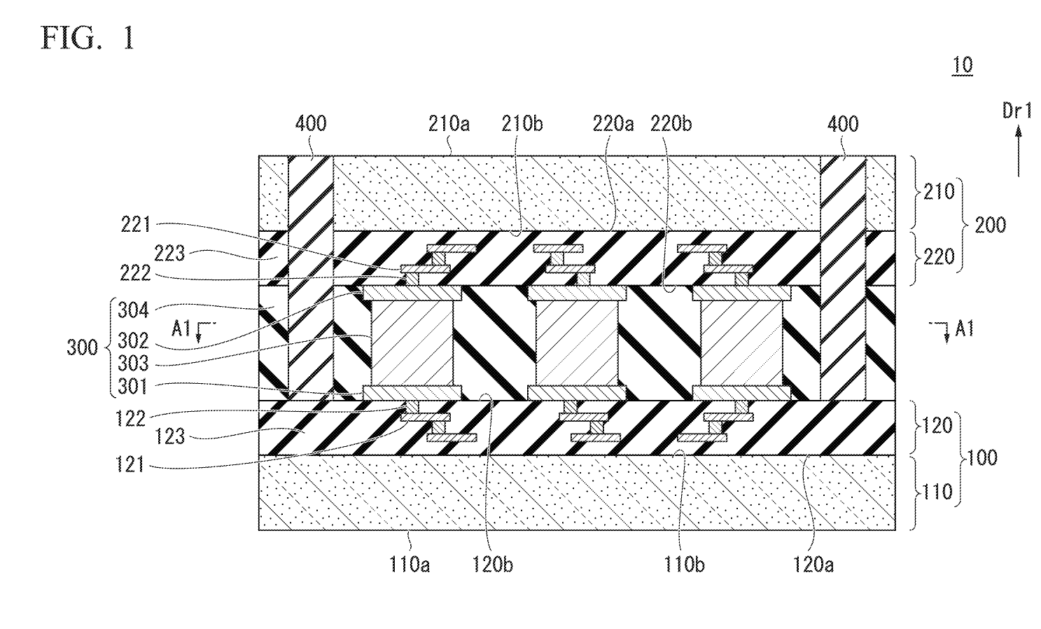

FIG. 1 shows a configuration of a semiconductor device 10 of a first embodiment of the present invention. In FIG. 1, a cross section of the semiconductor device 10 is shown. The semiconductor device 10 has a first substrate 100, a second substrate 200, a first connection portion 300, and an insulating layer 400. The first substrate 100 and the second substrate 200 are connected to each other via the first connection portion 300. The first substrate 100 and the second substrate 200 are stacked in a thickness direction Dr1 of the first substrate 100. The thickness direction Dr1 of the first substrate 100 is a direction perpendicular to a surface 110a of a first semiconductor layer 110.

The sizes of portions constituting the semiconductor device 10 may not conform to the sizes shown in FIG. 1. The sizes of the portions constituting the semiconductor device 10 may be set arbitrarily. The same will also apply to the sizes in the cross-sectional views other than FIG. 1.

The first substrate 100 has the first semiconductor layer 110 and a first wire layer 120. The first semiconductor layer 110 and the first wire layer 120 are stacked in the thickness direction Dr1 of the first substrate 100. In addition, the first semiconductor layer 110 and the first wire layer 120 are in contact with each other.

The first semiconductor layer 110 is constituted of a first semiconductor material. For example, the first semiconductor material is silicon (Si). The first semiconductor layer 110 has the surface 110a (first surface) and a surface 110b (second surface). The surface 110a of the first semiconductor layer 110 constitutes one of main surfaces of the first substrate 100. The main surface of the substrate is the widest surface among a plurality of surfaces constituting the outer surface of the substrate. The surface 110b of the first semiconductor layer 110 is in contact with the first wire layer 120.

The first wire layer 120 has first wires 121, first vias 122, and a first interlayer insulating film 123. In FIG. 1, there are a plurality of first wires 121, but the reference numeral is indicated for one first wire 121 representatively. In FIG. 1, there are a plurality of first vias 122, but the reference numeral is indicated for one first via 122 representatively.

The first wire layer 120 has a surface 120a (third surface) and a surface 120b (fourth surface). The surface 120a of the first wire layer 120 faces the surface 110b of the first semiconductor layer 110. The surface 120a of the first wire layer 120 is in contact with the surface 110b of the first semiconductor layer 110. The surface 120b of the first wire layer 120 constitutes one of main surfaces of the first substrate 100. The surface 120b of the first wire layer 120 faces the second substrate 200. The surface 120b of the first wire layer 120 is in contact with the first connection portion 300.

The first wires 121 and the first vias 122 are constituted of a first conductive material. For example, the first conductive material is metal such as aluminum (Al) and copper (Cu). The first wires 121 and the first vias 122 may be constituted of different conductive materials. Each of the first wires 121 is a thin film in which a wire pattern is formed. The first wires 121 transmit signals. Only one layer of the first wires 121 may be disposed, or a plurality of layers of the first wires 121 may be disposed. In the example shown in FIG. 1, two layers of the first wires 121 are disposed.

The first vias 122 connect two different layers of the first wires 121. In the first wire layer 120, portions other than the first wires 121 and the first vias 122 are formed by the first interlayer insulating film 123. The first interlayer insulating film 123 is constituted of a first insulating material. For example, the first insulating material is silicon dioxide (SiO2).

At least one of the first semiconductor layer 110 and the first wire layer 120 may have a circuit element such as a transistor.

As described above, the first substrate 100 has the first semiconductor layer 110 and the first wire layer 120. The first semiconductor layer 110 has the surface 110a (first surface) and the surface 110b (second surface) and contains the first semiconductor material. The first wire layer 120 has the surface 120a (third surface), the surface 120b (fourth surface), and the first wires 121. The surface 120a faces the surface 110b of the first semiconductor layer 110.

The second substrate 200 has a second semiconductor layer 210 and a second wire layer 220. The second semiconductor layer 210 and the second wire layer 220 are stacked in the thickness direction Dr1 of the first substrate 100. In addition, the second semiconductor layer 210 and the second wire layer 220 are in contact with each other.

The second semiconductor layer 210 is constituted of a second semiconductor material. The second semiconductor material is the same as the first semiconductor material constituting the first semiconductor layer 110. Alternatively, the second semiconductor material is different from the first semiconductor material. For example, the second semiconductor material is silicon (Si). The second semiconductor layer 210 has a surface 210a (fifth surface) and a surface 210b (sixth surface). The surface 210a of the second semiconductor layer 210 constitutes one of main surfaces of the second substrate 200. The surface 210b of the second semiconductor layer 210 is in contact with the second wire layer 220.

The second wire layer 220 has second wires 221, second vias 222, and a second interlayer insulating film 223. In FIG. 1, there are a plurality of second wires 221, but the reference numeral is indicated for one second wire 221 representatively. In FIG. 1, there are a plurality of second vias 222, but the reference numeral is indicated for one second via 222 representatively.

The second wire layer 220 has a surface 220a (seventh surface) and a surface 220b (eighth surface). The surface 220a of the second wire layer 220 faces the surface 210b of the second semiconductor layer 210. The surface 220a of the second wire layer 220 is in contact with the surface 210b of the second semiconductor layer 210. The surface 220b of the second wire layer 220 constitutes one of main surfaces of the second substrate 200. The surface 220b of the second wire layer 220 faces the first substrate 100. The surface 220b of the second wire layer 220 is in contact with the first connection portion 300.

The second wires 221 and the second vias 222 are constituted of a second conductive material. The second conductive material is the same as the first conductive material constituting the first wires 121 and the first vias 122. Alternatively, the second conductive material is different from the first conductive material. For example, the second conductive material is metal such as aluminum (Al) and copper (Cu). The second wires 221 and the second vias 222 may be constituted of different conductive materials. Each of the second wires 221 is a thin film in which a wire pattern is formed. The second wires 221 transmit signals. Only one layer of the second wires 221 may be disposed, or a plurality of layers of the second wires 221 may be disposed. In the example shown in FIG. 1, two layers of the second wires 221 are disposed.

The second vias 222 connect two different layers of the second wires 221. In the second wire layer 220, portions other than the second wires 221 and the second vias 222 are formed by the second interlayer insulating film 223. The second interlayer insulating film 223 is constituted of a second insulating material. The second insulating material is the same as the first insulating material constituting the first interlayer insulating film 123. Alternatively, the second insulating material is different from the first insulating material. For example, the second insulating material is silicon dioxide (SiO2).

At least one of the second semiconductor layer 210 and the second wire layer 220 may have the circuit element such as a transistor.

As described above, the second substrate 200 has the second semiconductor layer 210 and the second wire layer 220. The second semiconductor layer 210 has the surface 210a (fifth surface) and the surface 210b (sixth surface) and contains the second semiconductor material. The second wire layer 220 has the surface 220a (seventh surface), the surface 220b (eighth surface), and the second wires 221. The surface 220a faces the surface 210b of the second semiconductor layer 210.

The first substrate 100 and the second substrate 200 are disposed such that the first wire layer 120 and the second wire layer 220 face each other.

The first connection portions 300 are disposed between the first wire layer 120 and the second wire layer 220. The first connection portion 300 electrically connects the first wires 121 and the second wires 221 with each other. The first connection portion 300 has a first pad 301, a second pad 302, a first micro-bump 303, and a first resin layer 304. In FIG. 1, there are a plurality of first pads 301, but the reference numeral is indicated for one first pad 301 representatively. In FIG. 1, there are a plurality of second pads 302, but the reference numeral is indicated for one second pad 302 representatively. In FIG. 1, there are a plurality of first micro-bumps 303, but the reference numeral is indicated for one first micro-bump 303 representatively.

The first pads 301 are constituted of a conductive material. The conductive material constituting the first pads 301 is the same as the first conductive material constituting the first wires 121 and the first vias 122, or the second conductive material constituting the second wires 221 and the second vias 222. Alternatively, the conductive material constituting the first pads 301 is different from the first conductive material or the second conductive material. For example, the conductive material constituting the first pads 301 is metal such as gold (Au), copper (Cu), and nickel (Ni).

The first pads 301 are thin films. The first pads 301 are disposed on the surface 120b of the first wire layer 120. The first pads 301 are in contact with the first vias 122 on the surface 120b of the first wire layer 120. Therefore, the first pads 301 are electrically connected to the first wires 121.

The second pads 302 are constituted of a conductive material. The conductive material constituting the second pads 302 is the same as the first conductive material constituting the first wires 121 and the first vias 122, or the second conductive material constituting the second wires 221 and the second vias 222. Alternatively, the conductive material constituting the second pads 302 is different from the first conductive material or the second conductive material. For example, the conductive material constituting the second pads 302 is metal such as gold (Au), copper (Cu), and nickel (Ni).

The second pads 302 are thin films. The second pads 302 are disposed on the surface 220b of the second wire layer 220. The second pads 302 are in contact with the second vias 222 on the surface 220b of the second wire layer 220. Therefore, the second pads 302 are electrically connected to the second wires 221.

The first micro-bumps 303 are constituted of a conductive material. The conductive material constituting the first micro-bumps 303 is the same as the first conductive material constituting the first wires 121 and the first vias 122, or the second conductive material constituting the second wires 221 and the second vias 222. Alternatively, the conductive material constituting the first micro-bumps 303 is different from the first conductive material or the second conductive material. For example, the conductive material constituting the first micro-bumps 303 is metal such as gold (Au), copper (Cu), and nickel (Ni).

The first micro-bumps 303 are columnar structures. The first micro-bumps 303 may be spherical structures. The first micro-bumps 303 are disposed between the first pads 301 and the second pads 302 and are electrically connected to the first pads 301 and the second pads 302. Due to the configuration described above, the first pads 301, the second pads 302, and the first micro-bumps 303 are electrically connected to the first wires 121 and the second wires 221 and transmit signals between the first substrate 100 and the second substrate 200.

The first resin layer 304 is disposed between the first wire layer 120 and the second wire layer 220. The first resin layer 304 is constituted of a first resin material. For example, the first resin material is underfill resin. The first resin layer 304 covers the outer surfaces of the first pads 301, the second pads 302, and the first micro-bumps 303.

As described above, the first pads 301 are disposed on the surface 120b (fourth surface) of the first wire layer 120 and are electrically connected to the first wires 121. The second pads 302 are disposed on the surface 220b (eighth surface) of the second wire layer 220 and are electrically connected to the second wires 221. The first micro-bumps 303 are disposed between the first substrate 100 and the second substrate 200 and are electrically connected to the first pads 301 and the second pads 302. The first resin layer 304 is disposed between the first substrate 100 and the second substrate 200 and is in contact with the first pads 301, the second pads 302, and the first micro-bumps 303. The first resin layer 304 contains the first resin material.

The insulating layer 400 penetrates the second substrate 200 and the first resin layer 304. The insulating layer 400 is in contact with the surface 120b of the first wire layer 120. The insulating layer 400 contains an insulating material having hygroscopic properties lower than the hygroscopic properties of the first resin layer 304. For example, an insulating material constituting the insulating layer 400 is silicon nitride (SiN), silicon dioxide (SiO2), or the like. The hygroscopic properties of the insulating layer 400 are indicated on the basis of a coefficient of moisture absorption. The coefficient of moisture absorption of the insulating layer 400 is smaller than a coefficient of moisture absorption of the first resin layer 304.

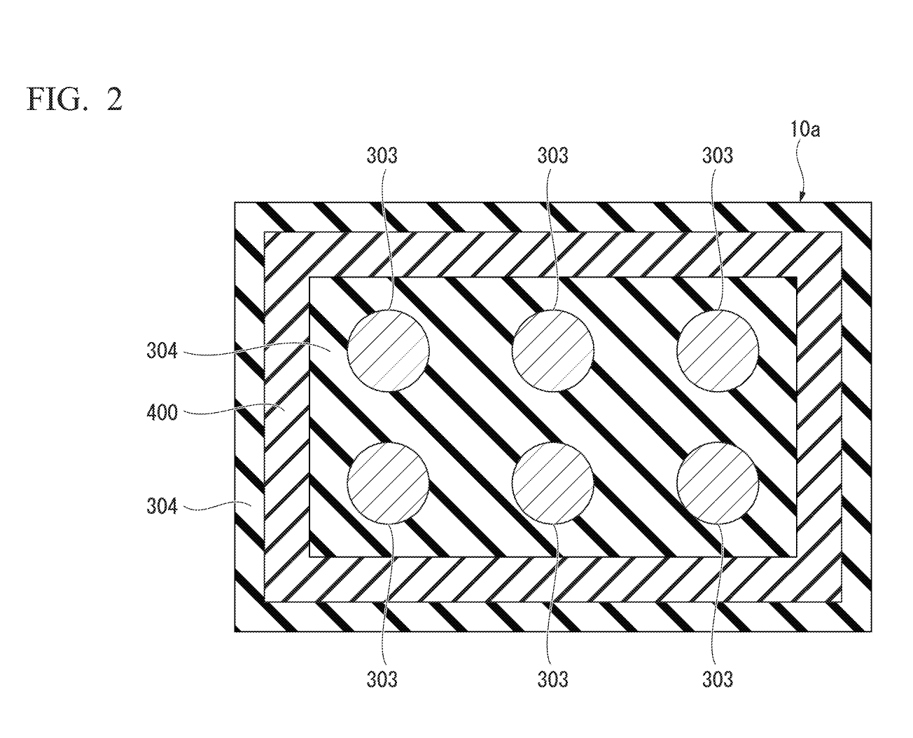

FIG. 2 shows a first cross section 10a of the semiconductor device 10 at a position A1 in FIG. 1. The first cross section 10a passes through the first micro-bumps 303, the first resin layer 304, and the insulating layer 400 and is parallel to the surface 110a of the first semiconductor layer 110.

As shown in FIG. 2, the semiconductor device 10 has the plurality of first micro-bumps 303. The plurality of first micro-bumps 303 are disposed in a circuit forming region including a central portion in the first cross section 10a. For example, the plurality of first micro-bumps 303 are disposed in a matrix. A cross section of the first micro-bump 303 has a circular shape. A cross section of the first micro-bump 303 may have a polygonal shape.

In the first cross section 10a, the insulating layer 400 is disposed such that the insulating layer 400 surrounds the plurality of first micro-bumps 303. That is, in the first cross section 10a, the plurality of first micro-bumps 303 are surrounded by the insulating layer 400. In the first cross section 10a, there is no cut end or gap in the insulating layer 400.

As described above, the insulating layer 400 contains an insulating material having hygroscopic properties lower than the hygroscopic properties of the first resin layer 304. The insulating layer 400 penetrates the second substrate 200 and the first resin layer 304. The insulating layer 400 surrounds the first micro-bumps 303 in the first cross section 10a which passes through the first micro-bumps 303, the first resin layer 304, and the insulating layer 400 and is parallel to the surface 110a (first surface) of the first semiconductor layer 110.

Similarly, in a cross section which passes through the first pads 301, the first resin layer 304, and the insulating layer 400 and is parallel to the surface 110a of the first semiconductor layer 110, the insulating layer 400 surrounds the first micro-bumps 303. Moreover, the insulating layer 400 surrounds the first micro-bumps 303 in a cross section which passes through the second pads 302, the first resin layer 304, and the insulating layer 400 and is parallel to the surface 110a of the first semiconductor layer 110.

The first resin layer 304 is exposed to the outside air at the tip end of the semiconductor device 10. That is, the first resin layer 304 comes in touch with the outside air at the tip end of the semiconductor device 10, so that moisture in the outside air infiltrates the first resin layer 304. Due to the low hygroscopic properties of the insulating layer 400, moisture is unlikely to infiltrate the insulating layer 400. In addition, since the insulating layer 400 penetrates the first resin layer 304, the insulating layer 400 blocks a pathway from the tip end to the first micro-bumps 303. Therefore, moisture in the outside air which has infiltrated the first resin layer 304 is unlikely to reach the first micro-bumps 303. As a result, in the semiconductor device 10, it is possible to reduce deformation of the first micro-bumps 303 caused due to moisture absorbed in the first resin layer 304.

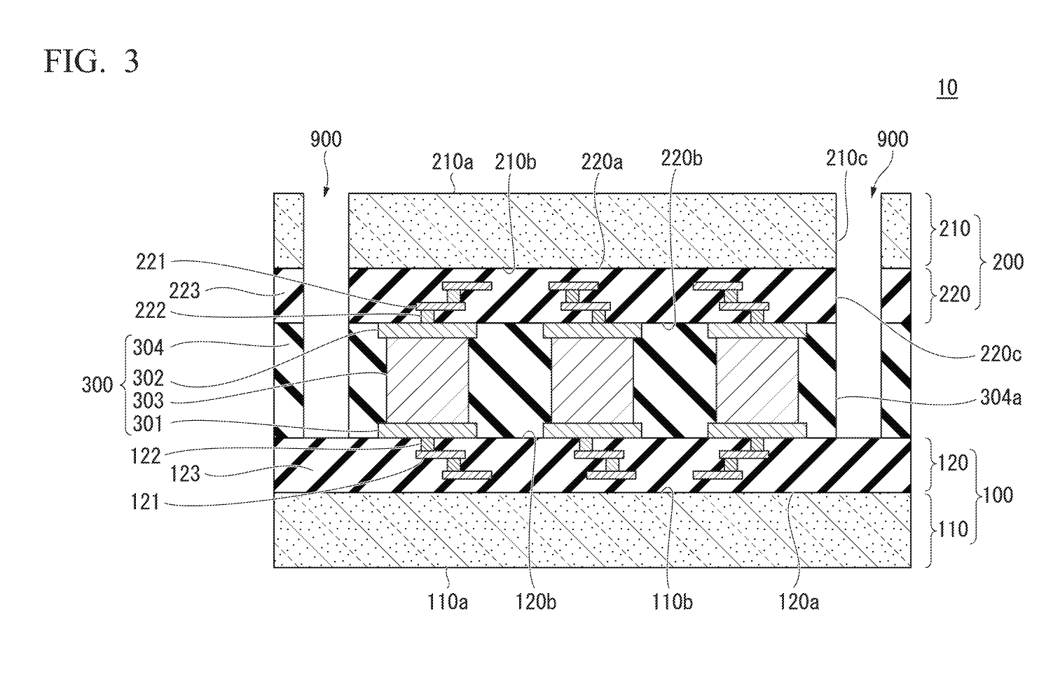

A method of manufacturing the insulating layer 400 will be described. FIG. 3 shows the semiconductor device 10 before the insulating layer 400 is formed therein. In FIG. 3, a cross section of the semiconductor device 10 is shown.

In a step of manufacturing the insulating layer 400, the second semiconductor layer 210, the second wire layer 220, and the first resin layer 304 are dug downward in that order from the side of the surface 210a of the second semiconductor layer 210. Accordingly, the surface 120b of the first wire layer 120 is exposed and a groove 900 is then formed. The semiconductor device 10 has the groove 900. The groove 900 is formed throughout the second semiconductor layer 210, the second wire layer 220, and the first resin layer 304.

The groove 900 includes a side surface 210c of the second semiconductor layer 210, a side surface 220c of the second wire layer 220, a side surface 304a of the first resin layer 304, and the surface 120b of the first wire layer 120. The insulating layer 400 is formed by filling the groove 900 with an insulating material. That is, the insulating layer 400 is disposed in the groove 900.

The semiconductor device according to each of the aspects of the present invention does not need to have a configuration which corresponds to at least one of the first via 122 and the second via 222.

According to the first embodiment, the semiconductor device 10 has the first substrate 100, the second substrate 200, the first pads 301, the second pads 302, the first micro-bumps 303, the first resin layer 304, and the insulating layer 400.

In the first embodiment, since the insulating layer 400 is disposed, moisture in the outside air which has infiltrated the first resin layer 304 is unlikely to reach the first micro-bumps 303. As a result, in the semiconductor device 10, it is possible to reduce deformation of the first micro-bumps 303 caused due to moisture absorbed in the first resin layer 304.

### Second Embodiment

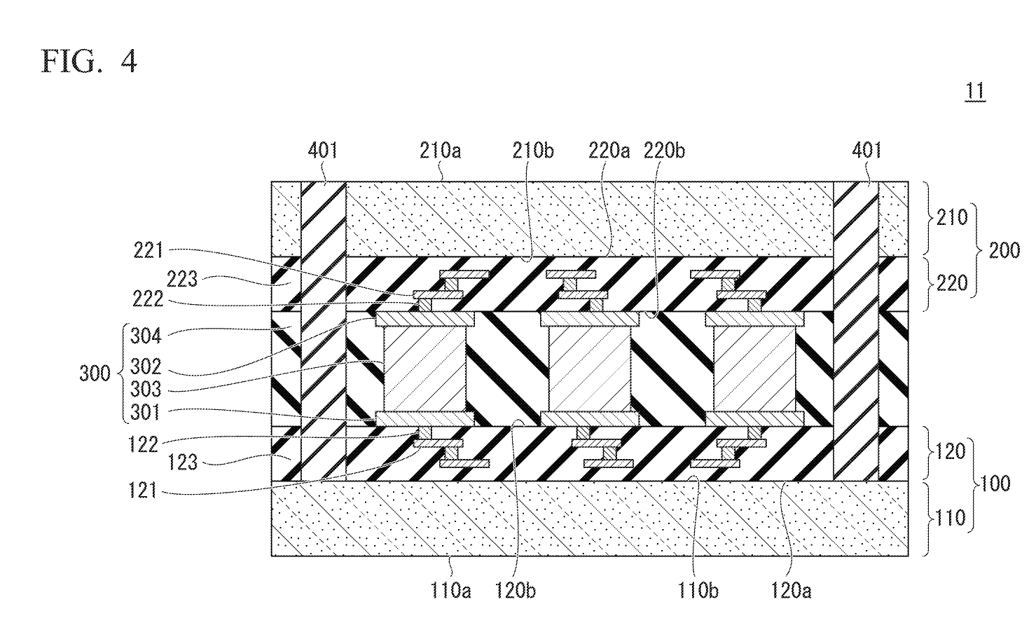

FIG. 4 shows a configuration of a semiconductor device 11 of a second embodiment of the present invention. In FIG. 4, a cross section of the semiconductor device 11 is shown. The semiconductor device 11 has the first substrate 100, the second substrate 200, the first connection portion 300, and an insulating layer 401.

The differences between FIGS. 4 and 1 will be described. The insulating layer 401 penetrates the second substrate 200, the first resin layer 304, and the first wire layer 120. A part of the insulating layer 401 is disposed inside the first substrate 100. The insulating layer 401 is in contact with the surface 110b of the first semiconductor layer 110. The insulating layer 401 is constituted of an insulating material similar to the insulating material constituting the insulating layer 400.

In regard to the matters other than those described above, the configuration shown in FIG. 4 is similar to the configuration shown in FIG. 1.

The disposition of each of the configurations, in a cross section which passes through the first micro-bumps 303, the first resin layer 304, and the insulating layer 401 and is parallel to the surface 110a of the first semiconductor layer 110, is similar to the disposition of each of the configurations shown in FIG. 2. That is, the insulating layer 401 is disposed such that the insulating layer 401 surrounds the plurality of first micro-bumps 303.

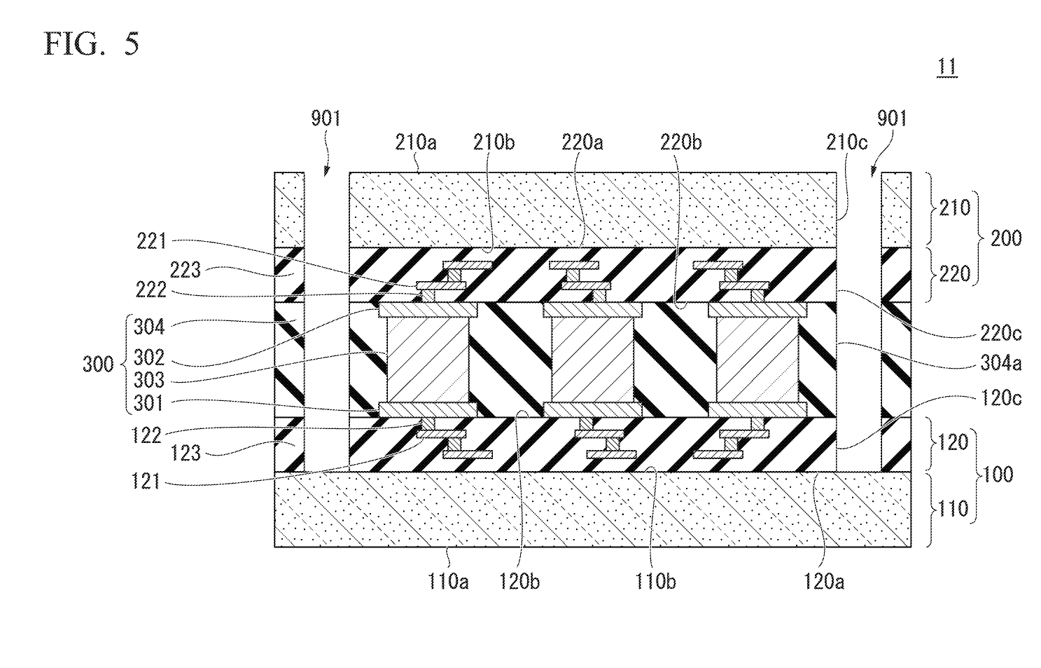

A method of manufacturing the insulating layer 401 will be described. FIG. 5 shows the semiconductor device 11 before the insulating layer 401 is formed therein. In FIG. 5, a cross section of the semiconductor device 11 is shown.

In a step of manufacturing the insulating layer 401, the second semiconductor layer 210, the second wire layer 220, the first resin layer 304, and the first wire layer 120 are dug downward in that order from the side of the surface 210a of the second semiconductor layer 210. Accordingly, the surface 110b of the first semiconductor layer 110 is exposed and a groove 901 is then formed. The semiconductor device 11 has the groove 901. The groove 901 is formed throughout the second semiconductor layer 210, the second wire layer 220, the first resin layer 304, and the first wire layer 120.

The groove 901 includes the side surface 210c of the second semiconductor layer 210, the side surface 220c of the second wire layer 220, the side surface 304a of the first resin layer 304, a side surface 120c of the first wire layer 120, and the surface 110b of the first semiconductor layer 110. The insulating layer 401 is formed by filling the groove 901 with an insulating material. That is, the insulating layer 401 is disposed in the groove 901.

In the first wire layer 120, the groove 901 is open on the surface 120a of the first wire layer 120 and the surface 120b of the first wire layer 120. That is, the groove 901 constitutes an opening portion on the surface 120a of the first wire layer 120 and an opening portion on the surface 120b of the first wire layer 120. The groove 901 may be open on only the surface 120b of the first wire layer 120. That is, the bottom surface of the groove 901 may be positioned between the surface 120a of the first wire layer 120 and the surface 120b of the first wire layer 120. In this case, the insulating layer 401 reaches the inside of the first wire layer 120 without penetrating the first wire layer 120.

According to the second embodiment, the semiconductor device 11 has the first substrate 100, the second substrate 200, the first pads 301, the second pads 302, the first micro-bumps 303, the first resin layer 304, and the insulating layer 401.

In the second embodiment, since the insulating layer 401 is disposed, moisture in the outside air which has infiltrated the first resin layer 304 is unlikely to reach the first micro-bumps 303. As a result, in the semiconductor device 11, it is possible to reduce deformation of the first micro-bumps 303 caused due to moisture absorbed in the first resin layer 304.

In the semiconductor device 10 of the first embodiment, there are cases in which the bonding strength between the insulating layer 400 and the first wire layer 120 is low. In such cases, there is a possibility that moisture in the outside air which has infiltrated the first resin layer 304 will infiltrate a boundary between the insulating layer 400 and the first wire layer 120. That is, there is a possibility that moisture will pass through a pathway including the boundary between the insulating layer 400 and the first wire layer 120. Meanwhile, in the semiconductor device 11 of the second embodiment, a pathway for moisture to pass through includes a boundary between the insulating layer 401 and the first wire layer 120, and a boundary between the insulating layer 401 and the first semiconductor layer 110. That is, in the semiconductor device 11 of the second embodiment, a pathway for moisture to pass through is longer than the pathway in the semiconductor device 10 of the first embodiment. Therefore, moisture in the outside air which has infiltrated the first resin layer 304 is less likely to reach the first micro-bumps 303. As a result, in the semiconductor device 11, it is possible to further reduce deformation of the first micro-bumps 303 caused due to moisture absorbed in the first resin layer 304.

### Third Embodiment

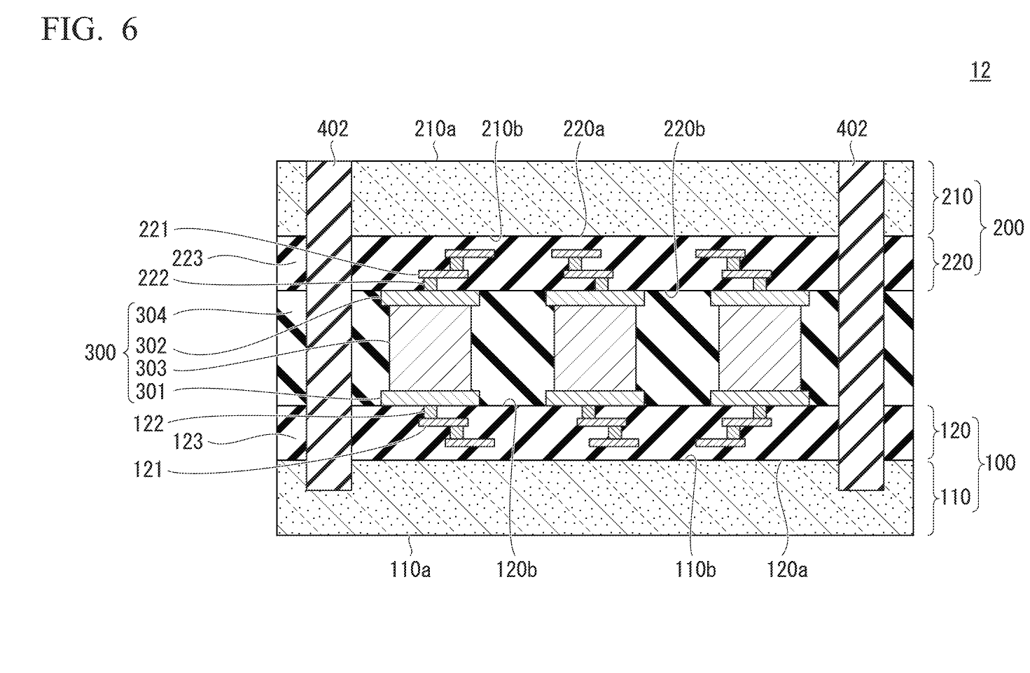

FIG. 6 shows a configuration of a semiconductor device 12 of a third embodiment of the present invention. In FIG. 6, a cross section of the semiconductor device 12 is shown. The semiconductor device 12 has the first substrate 100, the second substrate 200, the first connection portion 300, and an insulating layer 402.

The differences between FIGS. 6 and 1 will be described. The insulating layer 402 penetrates the second substrate 200, the first resin layer 304, and the first wire layer 120. A part of the insulating layer 402 is disposed inside the first substrate 100 and the first semiconductor layer 110. The insulating layer 402 is constituted of an insulating material similar to the insulating material constituting the insulating layer 400.

In regard to the matters other than those described above, the configuration shown in FIG. 6 is similar to the configuration shown in FIG. 1.

The disposition of each of the configurations, in a cross section which passes through the first micro-bumps 303, the first resin layer 304, and the insulating layer 402 and is parallel to the surface 110a of the first semiconductor layer 110, is similar to the disposition of each of the configurations shown in FIG. 2. That is, the insulating layer 402 is disposed such that the insulating layer 402 surrounds the plurality of first micro-bumps 303.

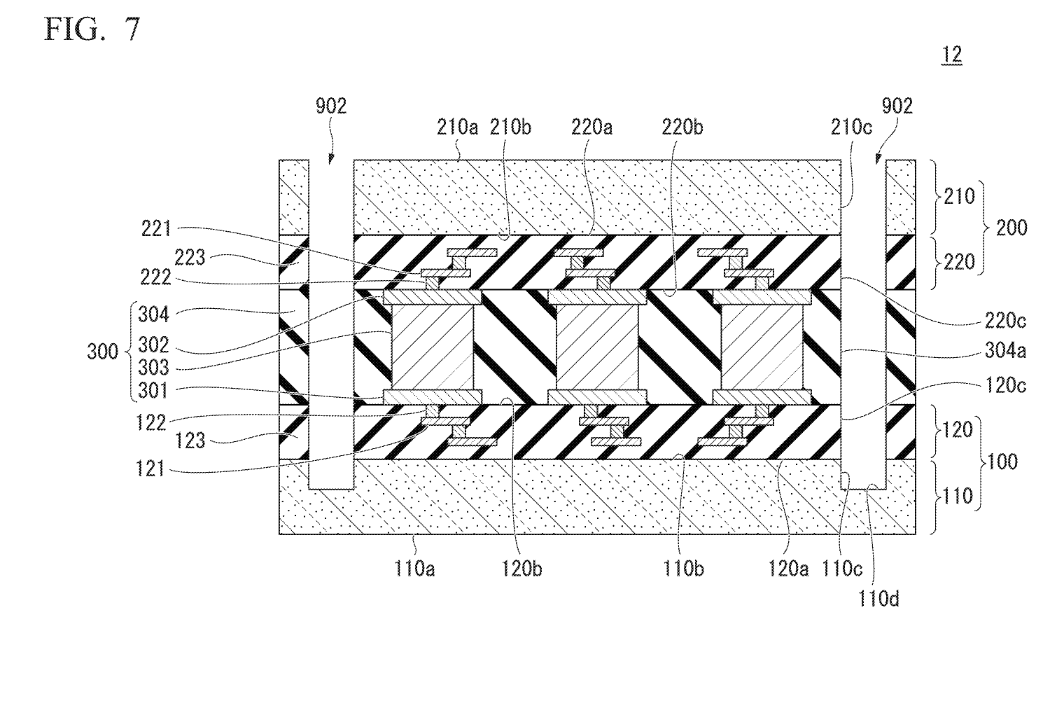

A method of manufacturing the insulating layer 402 will be described. FIG. 7 shows the semiconductor device 12 before the insulating layer 402 is formed therein. In FIG. 7, a cross section of the semiconductor device 12 is shown.

In a step of manufacturing the insulating layer 402, the second semiconductor layer 210, the second wire layer 220, the first resin layer 304, the first wire layer 120, and the first semiconductor layer 110 are dug downward in that order from the side of the surface 210a of the second semiconductor layer 210. Accordingly, the first semiconductor layer 110 is exposed and a groove 902 is then formed. The semiconductor device 12 has the groove 902. The groove 902 is formed throughout the second semiconductor layer 210, the second wire layer 220, the first resin layer 304, the first wire layer 120, and the first semiconductor layer 110.

The groove 902 includes the side surface 210c of the second semiconductor layer 210, the side surface 220c of the second wire layer 220, the side surface 304a of the first resin layer 304, the side surface 120c of the first wire layer 120, a side surface 110c of the first semiconductor layer 110, and a surface 110d of the first semiconductor layer 110. The insulating layer 402 is formed by filling the groove 902 with an insulating material. That is, the insulating layer 402 is disposed in the groove 902.

In the first wire layer 120, the groove 902 is open on the surface 120a of the first wire layer 120 and the surface 120b of the first wire layer 120. That is, the groove 902 constitutes the opening portion on the surface 120a of the first wire layer 120 and the opening portion on the surface 120b of the first wire layer 120. In the first semiconductor layer 110, the groove 902 is open on the surface 110b of the first semiconductor layer 110. That is, the groove 902 constitutes an opening portion on the surface 110b of the first semiconductor layer 110.

According to the third embodiment, the semiconductor device 12 has the first substrate 100, the second substrate 200, the first pads 301, the second pads 302, the first micro-bumps 303, the first resin layer 304, and the insulating layer 402.

In the third embodiment, since the insulating layer 402 is disposed, moisture in the outside air which has infiltrated the first resin layer 304 is unlikely to reach the first micro-bumps 303. As a result, in the semiconductor device 12, it is possible to reduce deformation of the first micro-bumps 303 caused due to moisture absorbed in the first resin layer 304.

In the semiconductor device 12 of the third embodiment, a pathway for moisture to pass through is longer than the pathway in the semiconductor device 11 of the second embodiment. Therefore, moisture in the outside air which has infiltrated the first resin layer 304 is less likely to reach the first micro-bumps 303. As a result, in the semiconductor device 12, it is possible to further reduce deformation of the first micro-bumps 303 caused due to moisture absorbed in the first resin layer 304.

### Fourth Embodiment

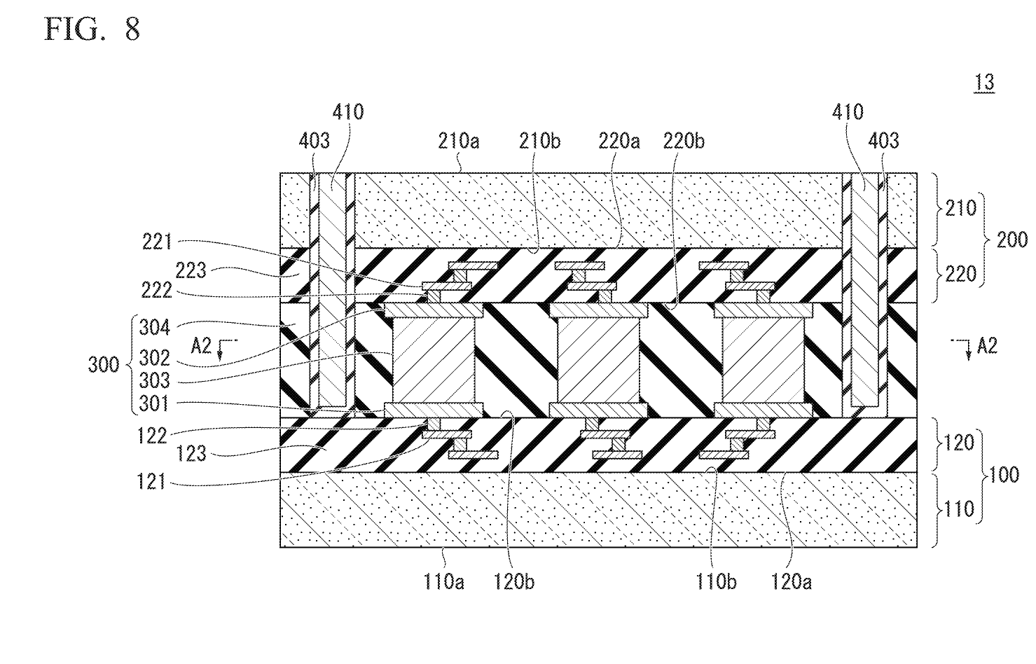

FIG. 8 shows a configuration of a semiconductor device 13 of a fourth embodiment of the present invention. In FIG. 8, a cross section of the semiconductor device 13 is shown. The semiconductor device 13 has the first substrate 100, the second substrate 200, the first connection portion 300, an insulating layer 403, and a metal layer 410.

The differences between FIGS. 8 and 1 will be described. The insulating layer 403 penetrates the second substrate 200 and the first resin layer 304. The insulating layer 403 is in contact with the surface 120b of the first wire layer 120. The insulating layer 403 is constituted of an insulating material similar to the insulating material constituting the insulating layer 400.

The metal layer 410 is disposed inside the insulating layer 403. The metal layer 410 penetrates the second substrate 200. A part of the metal layer 410 is disposed inside the first resin layer 304. The metal layer 410 is constituted of a metal material. A side surface and the bottom surface of the metal layer 410 are in contact with the insulating layer 403. The bottom surface of the metal layer 410 may be in contact with the surface 120b of the first wire layer 120.

The hygroscopic properties of the metal layer 410 are lower than the hygroscopic properties of the insulating layer 403. Therefore, even when moisture infiltrates the insulating layer 403, the moisture is unlikely to pass through the metal layer 410. That is, moisture in the outside air which has infiltrated the first resin layer 304 is unlikely to reach the first micro-bumps 303. As a result, in the semiconductor device 13, it is possible to reduce deformation of the first micro-bumps 303 caused due to moisture absorbed in the first resin layer 304.

In regard to the matters other than those described above, the configuration shown in FIG. 8 is similar to the configuration shown in FIG. 1.

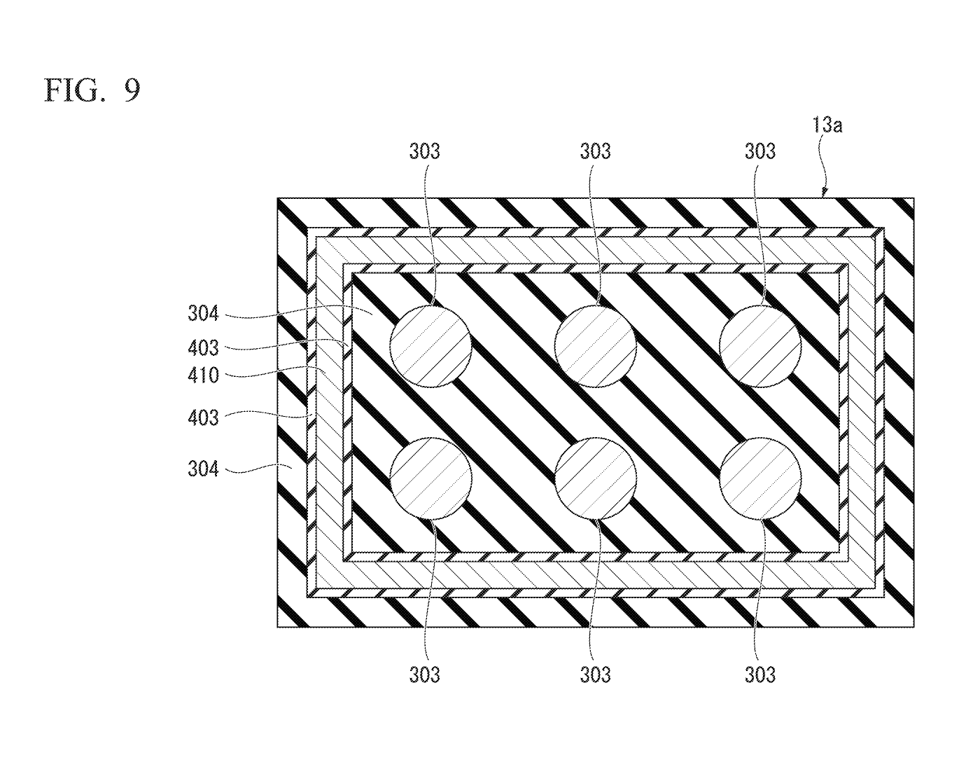

FIG. 9 shows a first cross section 13a of the semiconductor device 13 at a position A2 in FIG. 8. The first cross section 13a passes through the first micro-bumps 303, the first resin layer 304, the insulating layer 403, and the metal layer 410 and is parallel to the surface 110a of the first semiconductor layer 110.

In the first cross section 13a, the insulating layer 403 and the metal layer 410 are disposed such that the insulating layer 403 and the metal layer 410 surround the plurality of first micro-bumps 303. That is, in the first cross section 13a, the plurality of first micro-bumps 303 are surrounded by the insulating layer 403 and the metal layer 410. In the first cross section 13a, there is no cut end or gap in the insulating layer 403 and the metal layer 410. Since the metal layer 410 is surrounded by the insulating layer 403, the metal layer 410 does not affect a signal transmitted through the first connection portion 300.

In the first cross section 13a, the insulating layer 403 is disposed such that the insulating layer 403 surrounds the metal layer 410. That is, in the first cross section 13a, the metal layer 410 is surrounded by the insulating layer 403.

As described above, the metal layer 410 contains a metal material. The metal layer 410 penetrates the second substrate 200 and is disposed inside the first resin layer 304. In the first cross section 13a, the metal layer 410 surrounds the first micro-bumps 303. In the first cross section 13a, the insulating layer 403 surrounds the metal layer 410. That is, the insulating layer 403 has a first portion (outer portion) and a second portion (inner portion). In the first cross section 13a, the first portion surrounds the metal layer 410 and the second portion. In the first cross section 13a, the metal layer 410 is disposed between the first portion and the second portion.

Similarly, in a cross section which passes through the first pads 301, the first resin layer 304, and the insulating layer 403 and is parallel to the surface 110a of the first semiconductor layer 110, the metal layer 410 surrounds the first micro-bumps 303, and the insulating layer 403 surrounds the metal layer 410. Moreover, in a cross section which passes through the second pads 302, the first resin layer 304, and the insulating layer 403 and is parallel to the surface 110a of the first semiconductor layer 110, the metal layer 410 surrounds the first micro-bumps 303, and the insulating layer 403 surrounds the metal layer 410.

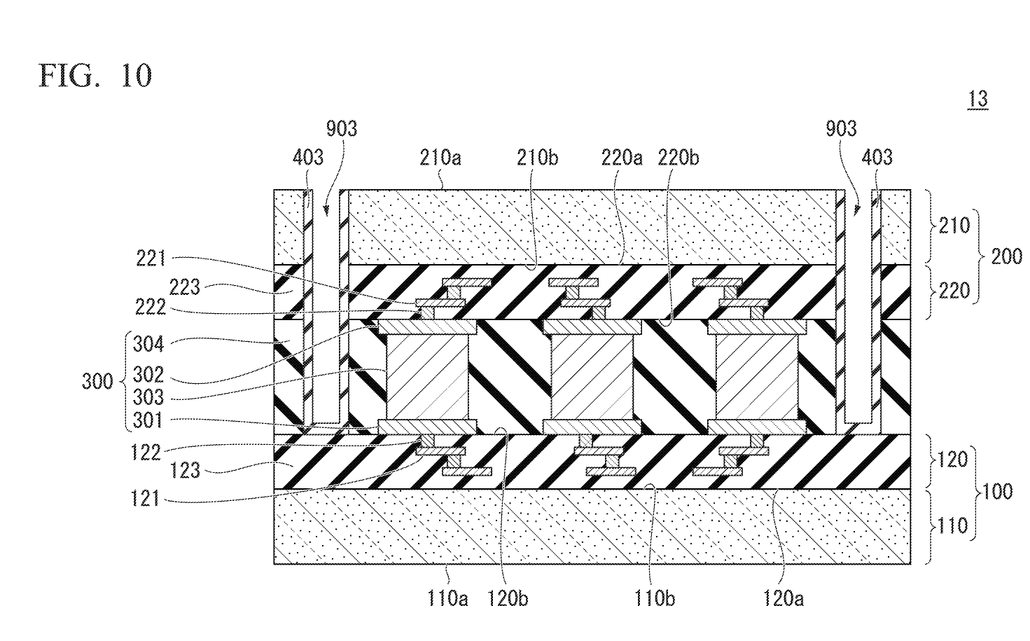

A method of manufacturing the metal layer 410 will be described. FIG. 10 shows a semiconductor device 13 before the metal layer 410 is formed therein. In FIG. 10, a cross section of the semiconductor device 13 is shown.

After the groove 900 shown in FIG. 3 is formed, an insulating material is attached to the groove 900 such that the outer surface of the groove 900 is covered therewith. Accordingly, the insulating layer 403 is formed. FIG. 10 shows the semiconductor device 13 after the insulating layer 403 is formed. The outer surface of the insulating layer 403 constitutes a groove 903. The metal layer 410 is formed by filling the groove 903 with a metal material. That is, the metal layer 410 is disposed in the groove 903.

According to the fourth embodiment, the semiconductor device 13 has the first substrate 100, the second substrate 200, the first pads 301, the second pads 302, the first micro-bumps 303, the first resin layer 304, the insulating layer 403, and the metal layer 410.

In the fourth embodiment, since the insulating layer 403 is disposed, moisture in the outside air which has infiltrated the first resin layer 304 is unlikely to reach the first micro-bumps 303. As a result, in the semiconductor device 13, it is possible to reduce deformation of the first micro-bumps 303 caused due to moisture absorbed in the first resin layer 304.

In the fourth embodiment, since the metal layer 410 is disposed, moisture in the outside air which has infiltrated the first resin layer 304 is less likely to reach the first micro-bumps 303. As a result, in the semiconductor device 13, it is possible to further reduce deformation of the first micro-bumps 303 caused due to moisture absorbed in the first resin layer 304.

### Fifth Embodiment

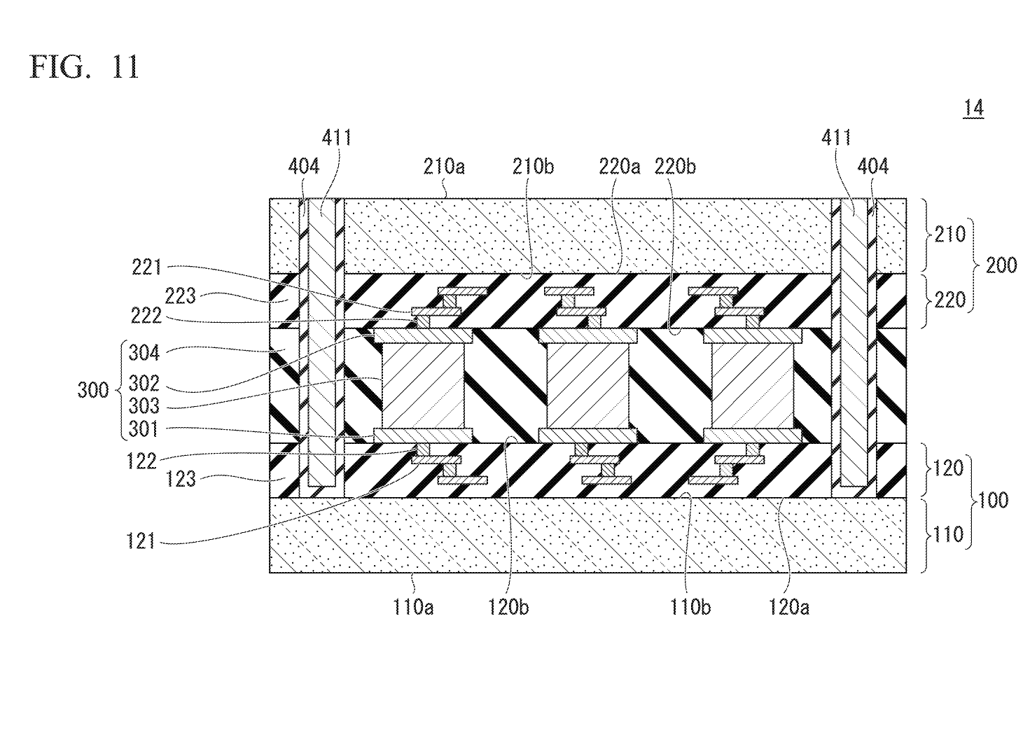

FIG. 11 shows a configuration of a semiconductor device 14 of a fifth embodiment of the present invention. In FIG. 11, a cross section of the semiconductor device 14 is shown. The semiconductor device 14 has the first substrate 100, the second substrate 200, the first connection portion 300, an insulating layer 404, and a metal layer 411.

The differences between FIGS. 11 and 8 will be described. The insulating layer 404 penetrates the second substrate 200, the first resin layer 304, and the first wire layer 120. A part of the insulating layer 404 is disposed inside the first substrate 100. The insulating layer 404 is in contact with the surface 110b of the first semiconductor layer 110. The insulating layer 404 is constituted of an insulating material similar to the insulating material constituting the insulating layer 400.

The metal layer 411 penetrates the second substrate 200 and the first resin layer 304. A part of the metal layer 411 is disposed inside the first substrate 100 and the first wire layer 120. The metal layer 411 is constituted of a metal material similar to the metal material constituting the metal layer 410.

In regard to the matters other than those described above, the configuration shown in FIG. 11 is similar to the configuration shown in FIG. 8.

The disposition of each of the configurations, in a cross section which passes through the first micro-bumps 303, the first resin layer 304, the insulating layer 404, and the metal layer 411 and is parallel to the surface 110a of the first semiconductor layer 110, is similar to the disposition of each of the configurations shown in FIG. 9. That is, the insulating layer 404 and the metal layer 411 are disposed such that the insulating layer 404 and the metal layer 411 surround the plurality of first micro-bumps 303. The insulating layer 404 is disposed such that the insulating layer 404 surrounds the metal layer 411.

After the groove 901 shown in FIG. 5 is formed, an insulating material is attached to the groove 901 such that the outer surface of the groove 901 is covered therewith. Accordingly, the insulating layer 404 is formed. The metal layer 411 is formed when a groove constituted by the outer surface of the insulating layer 404 is filled with a metal material.

According to the fifth embodiment, the semiconductor device 14 has the first substrate 100, the second substrate 200, the first pads 301, the second pads 302, the first micro-bumps 303, the first resin layer 304, the insulating layer 404, and the metal layer 411.

In the fifth embodiment, since the insulating layer 404 is disposed, moisture in the outside air which has infiltrated the first resin layer 304 is unlikely to reach the first micro-bump 303. As a result, in the semiconductor device 14, it is possible to reduce deformation of the first micro-bumps 303 caused due to moisture absorbed in the first resin layer 304.

In the fifth embodiment, since the metal layer 411 is disposed, moisture in the outside air which has infiltrated the first resin layer 304 is less likely to reach the first micro-bumps 303. As a result, in the semiconductor device 14, it is possible to further reduce deformation of the first micro-bumps 303 caused due to moisture absorbed in the first resin layer 304.

In the semiconductor device 14 of the fifth embodiment, a pathway for moisture to pass through is longer than the pathway in the semiconductor device 13 of the fourth embodiment. Therefore, moisture in the outside air which has infiltrated the first resin layer 304 is less likely to reach the first micro-bumps 303. As a result, in the semiconductor device 14, it is possible to further reduce deformation of the first micro-bumps 303 caused due to moisture absorbed in the first resin layer 304.

### Sixth Embodiment

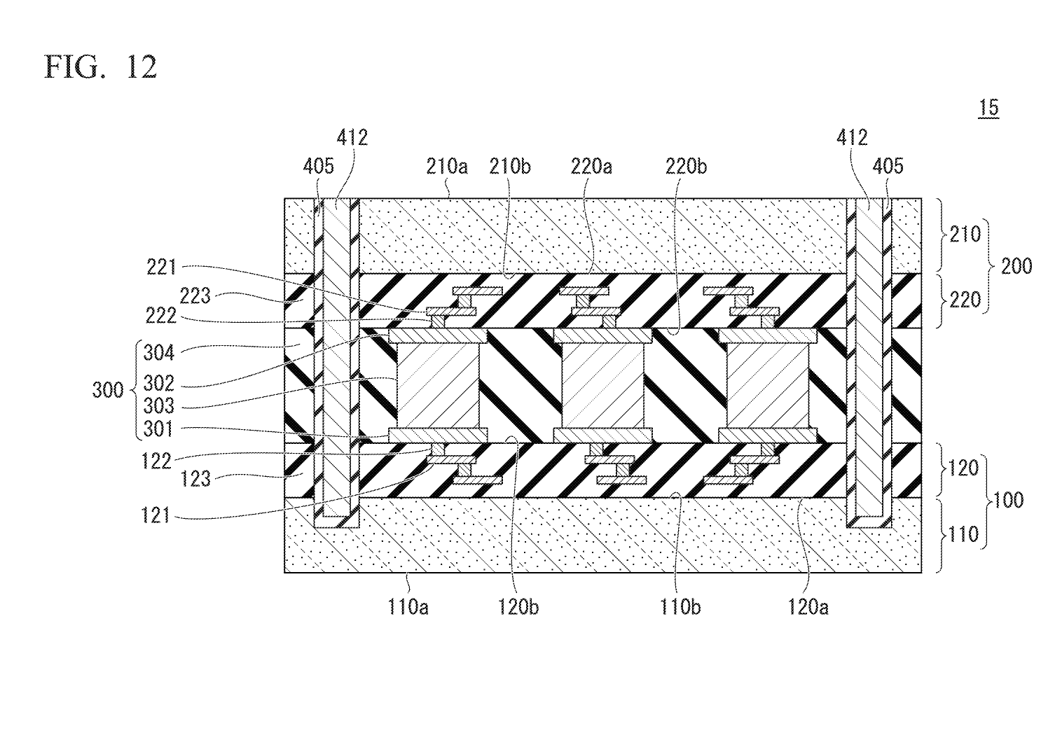

FIG. 12 shows a configuration of a semiconductor device 15 of a sixth embodiment of the present invention. In FIG. 12, a cross section of the semiconductor device 15 is shown. The semiconductor device 15 has the first substrate 100, the second substrate 200, the first connection portion 300, an insulating layer 405, and a metal layer 412.

The differences between FIGS. 12 and 8 will be described. The insulating layer 405 penetrates the second substrate 200, the first resin layer 304, and the first wire layer 120. A part of the insulating layer 405 is disposed inside the first substrate 100 and the first semiconductor layer 110. The insulating layer 405 is constituted of an insulating material similar to the insulating material constituting the insulating layer 400.

The metal layer 412 penetrates the second substrate 200, the first resin layer 304, and the first wire layer 120. A part of the metal layer 412 is disposed inside the first substrate 100 and the first semiconductor layer 110. The metal layer 412 is constituted of a metal material similar to the metal material constituting the metal layer 410.

In regard to the matters other than those described above, the configuration shown in FIG. 12 is similar to the configuration shown in FIG. 8.

The disposition of each of the configurations in a cross section which passes through the first micro-bumps 303, the first resin layer 304, the insulating layer 405, and the metal layer 412 and is parallel to the surface 110a of the first semiconductor layer 110, is similar to the disposition of each of the configurations shown in FIG. 9. That is, the insulating layer 405 and the metal layer 412 are disposed such that the insulating layer 405 and the metal layer 412 surround the plurality of first micro-bumps 303. The insulating layer 405 is disposed such that the insulating layer 405 surrounds the metal layer 412.

After the groove 902 shown in FIG. 7 is formed, an insulating material is attached to the groove 902 such that the outer surface of the groove 902 is covered therewith. Accordingly, the insulating layer 405 is formed. The metal layer 412 is formed when a groove constituted by the outer surface of the insulating layer 405 is filled with a metal material.

According to the sixth embodiment, the semiconductor device 15 has the first substrate 100, the second substrate 200, the first pads 301, the second pads 302, the first micro-bumps 303, the first resin layer 304, the insulating layer 405, and the metal layer 412.

In the sixth embodiment, since the insulating layer 405 is disposed, moisture in the outside air which has infiltrated the first resin layer 304 is unlikely to reach the first micro-bump 303. As a result, in the semiconductor device 15, it is possible to reduce deformation of the first micro-bumps 303 caused due to moisture absorbed in the first resin layer 304.

In the sixth embodiment, since the metal layer 412 is disposed, moisture in the outside air which has infiltrated the first resin layer 304 is less likely to reach the first micro-bumps 303. As a result, in the semiconductor device 15, it is possible to further reduce deformation of the first micro-bumps 303 caused due to moisture absorbed in the first resin layer 304.

In the semiconductor device 15 of the sixth embodiment, a pathway for moisture to pass through is longer than the pathway in the semiconductor device 14 of the fifth embodiment. Therefore, moisture in the outside air which has infiltrated the first resin layer 304 is less likely to reach the first micro-bumps 303. As a result, in the semiconductor device 15, it is possible to further reduce deformation of the first micro-bumps 303 caused due to moisture absorbed in the first resin layer 304.

### Seventh Embodiment

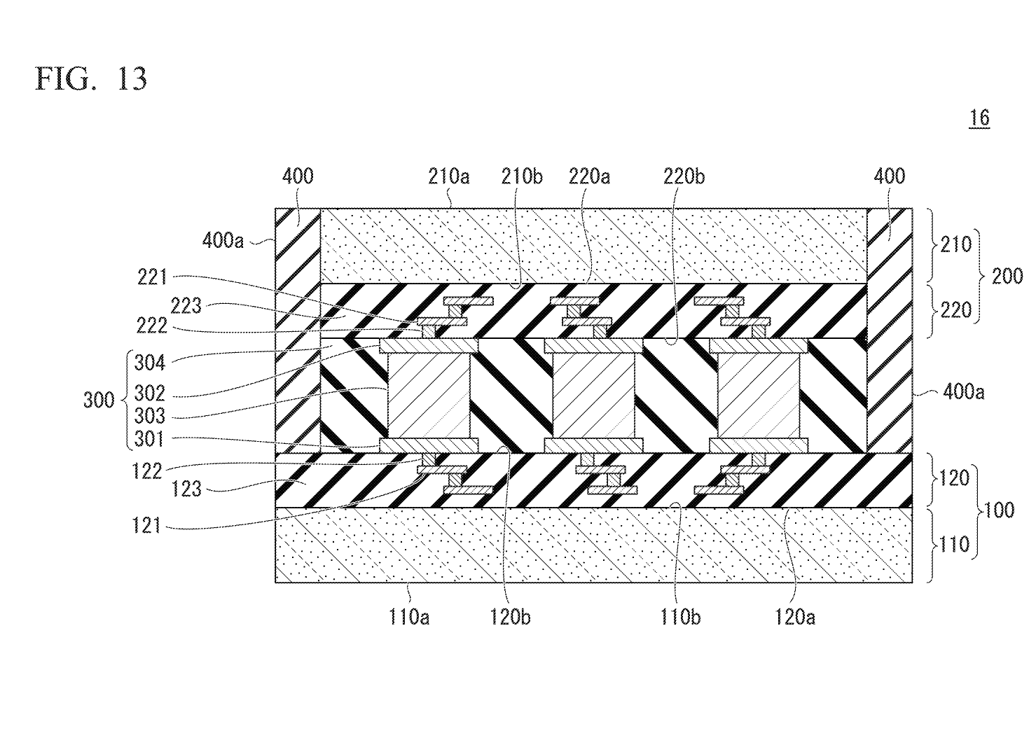

FIG. 13 shows a configuration of a semiconductor device 16 of a seventh embodiment of the present invention. In FIG. 13, a cross section of the semiconductor device 16 is shown. The semiconductor device 16 has the first substrate 100, the second substrate 200, the first connection portion 300, and the insulating layer 400.

The differences between FIGS. 13 and 1 will be described. The insulating layer 400 is disposed in an end portion (tip end) of the semiconductor device 16. That is, the insulating layer 400 includes an end portion of the semiconductor device 16. Therefore, a side surface 400a of the insulating layer 400 is exposed to the outside air.

In a step of manufacturing the semiconductor device 16, structures of a plurality of semiconductor devices 16 are formed in a substrate including the first substrate 100 and the second substrate 200. Thereafter, the substrate is cut at positions at the end portions of the semiconductor devices 16, thereby completing manufacturing each of the semiconductor devices 16. In the step of manufacturing the semiconductor device 10 shown in FIG. 1, the substrate is cut at the end portions of the semiconductor device 10, thereby completing manufacturing each of the semiconductor devices 10.

As shown in FIG. 2, in the semiconductor device 10, structures of the first resin layer 304 and the like are disposed outside the insulating layer 400. Meanwhile, in the semiconductor device 16, since the insulating layer 400 is disposed in the end portion of the semiconductor device 16, no structure is required to be disposed outside the insulating layer 400. Therefore, the area of the semiconductor device 16 is reduced. As a result, in the semiconductor device 16, compared to the semiconductor device 10, the number of semiconductor devices which can be obtained per unit area of a substrate increases. In FIG. 13, the lateral width of the semiconductor device 16 is substantially the same as the lateral width of the semiconductor device 10. However, the lateral width of the semiconductor device 16 can be narrower than the lateral width of the semiconductor device 10 by shortening the distance between the insulating layer 400 and the first micro-bumps 303.

In regard to the matters other than those described above, the configuration shown in FIG. 13 is similar to the configuration shown in FIG. 1.

In place of the insulating layer 400, the insulating layer 401 shown in FIG. 4 may be disposed. In place of the insulating layer 400, the insulating layer 402 shown in FIG. 6 may be disposed. In place of the insulating layer 400, the insulating layer 403 and the metal layer 410 shown in FIG. 8 may be disposed. In place of the insulating layer 400, the insulating layer 404 and the metal layer 411 shown in FIG. 11 may be disposed. In place of the insulating layer 400, the insulating layer 405 and the metal layer 412 shown in FIG. 12 may be disposed.

According to the seventh embodiment, the semiconductor device 16 has the first substrate 100, the second substrate 200, the first pads 301, the second pads 302, the first micro-bumps 303, the first resin layer 304, and the insulating layer 400.

In the seventh embodiment, since the insulating layer 400 is disposed, moisture in the outside air which has infiltrated the first resin layer 304 is unlikely to reach the first micro-bump 303. As a result, in the semiconductor device 16, it is possible to reduce deformation of the first micro-bumps 303 caused due to moisture absorbed in the first resin layer 304.

### Eighth Embodiment

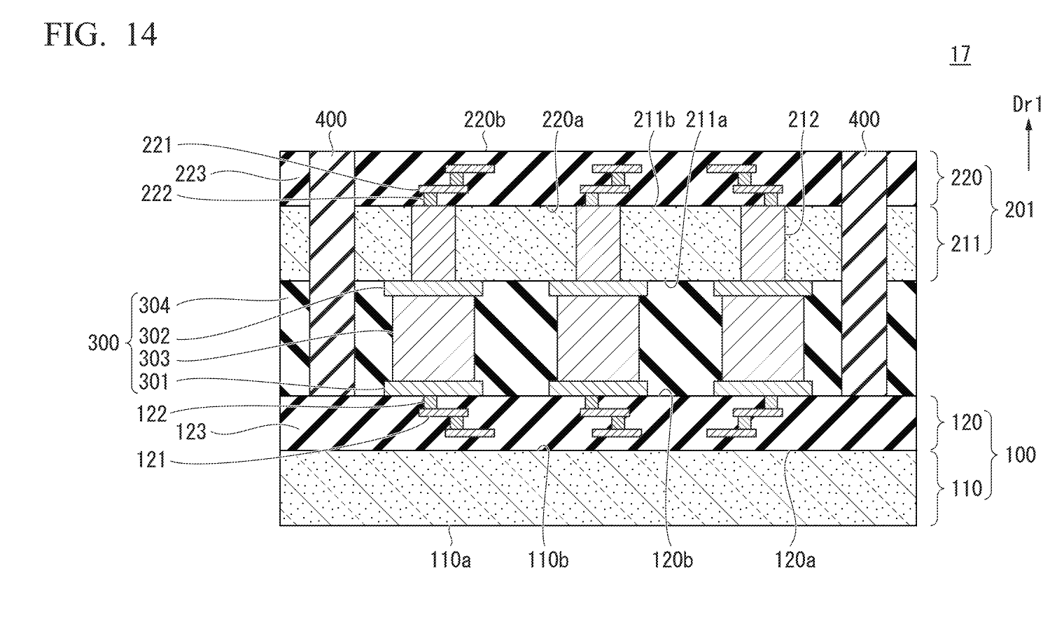

FIG. 14 shows a configuration of a semiconductor device 17 of an eighth embodiment of the present invention. In FIG. 14, a cross section of the semiconductor device 17 is shown. The semiconductor device 17 has the first substrate 100, a second substrate 201, the first connection portion 300, and the insulating layer 400. The first substrate 100 and the second substrate 201 are connected to each other via the first connection portion 300. The first substrate 100 and the second substrate 201 are stacked in the thickness direction Dr1 of the first substrate 100.

The differences between FIGS. 14 and 1 will be described. The second substrate 201 has a second semiconductor layer 211 and the second wire layer 220. The second semiconductor layer 211 and the second wire layer 220 are stacked in the thickness direction Dr1 of the first substrate 100. In addition, the second semiconductor layer 211 and the second wire layer 220 are in contact with each other.

The second semiconductor layer 211 is constituted of the same second semiconductor material as the second semiconductor material constituting the second semiconductor layer 210. The second semiconductor layer 211 has a surface 211a (fifth surface) and a surface 211b (sixth surface). The surface 211a of the second semiconductor layer 211 constitutes one of main surfaces of the second substrate 201. The surface 211a of the second semiconductor layer 211 faces the first substrate 100. The surface 211a of the second semiconductor layer 211 is in contact with the first connection portion 300. The surface 211b of the second semiconductor layer 211 is in contact with the second wire layer 220.

The second semiconductor layer 211 has second through-vias 212. In FIG. 14, there are a plurality of second through-vias 212, but the reference numeral is indicated for one second through-via 212 representatively. The second through-vias 212 penetrate the second semiconductor layer 211. The second through-vias 212 are in contact with the second vias 222 on the surface 220a of the second wire layer 220. Therefore, the second through-vias 212 are electrically connected to the second wires 221. The second through-vias 212 are in contact with the second pads 302 on the surface 211a of the second semiconductor layer 211.

The surface 220a of the second wire layer 220 faces the surface 211b of the second semiconductor layer 211. The surface 220a of the second wire layer 220 is in contact with the surface 211b of the second semiconductor layer 211. The surface 220b of the second wire layer 220 constitutes one of main surfaces of the second substrate 201.

At least one of the second semiconductor layer 211 and the second wire layer 220 may have a circuit element such as a transistor.

The first substrate 100 and the second substrate 201 are disposed such that the first wire layer 120 and the second semiconductor layer 211 face each other.

The first connection portions 300 are disposed between the first wire layer 120 and the second semiconductor layer 211. The second pads 302 are disposed on the surface 211a of the second semiconductor layer 211. The second pads 302 are in contact with the second through-vias 212 on the surface 211a of the second semiconductor layer 211. Therefore, the second pads 302 are electrically connected to the second wires 221.

As described above, the second semiconductor layer 211 has the second through-vias 212 which penetrate the second semiconductor layer 211. The second pads 302 are disposed on the surface 211a (fifth surface) of the second semiconductor layer 211 and are electrically connected to the second wires 221 by the second through-vias 212.

In regard to the matters other than those described above, the configuration shown in FIG. 14 is similar to the configuration shown in FIG. 1.

In place of the insulating layer 400, the insulating layer 401 shown in FIG. 4 may be disposed. In place of the insulating layer 400, the insulating layer 402 shown in FIG. 6 may be disposed. In place of the insulating layer 400, the insulating layer 403 and the metal layer 410 shown in FIG. 8 may be disposed. In place of the insulating layer 400, the insulating layer 404 and the metal layer 411 shown in FIG. 11 may be disposed. In place of the insulating layer 400, the insulating layer 405 and the metal layer 412 shown in FIG. 12 may be disposed.

In the semiconductor device 10 of the first embodiment, the second pads 302 are disposed on the surface 220b of the second wire layer 220. In the semiconductor device 17 of the eighth embodiment, the second pads 302 are disposed on the surface 211a of the second semiconductor layer 211. Therefore, in the semiconductor device according to each of the aspects of the present invention, the configuration is acceptable as long as the second pads are disposed on the fifth surface of the second semiconductor layer or the eighth surface of the second wire layer.

The semiconductor device according to each of the aspects of the present invention does not need to have a configuration which corresponds to the second through-via 212.

According to the eighth embodiment, the semiconductor device 17 has the first substrate 100, the second substrate 201, the first pads 301, the second pads 302, the first micro-bumps 303, the first resin layer 304, and the insulating layer 400.

In the eighth embodiment, since the insulating layer 400 is disposed, moisture in the outside air which has infiltrated the first resin layer 304 is unlikely to reach the first micro-bump 303. As a result, in the semiconductor device 17, it is possible to reduce deformation of the first micro-bumps 303 caused due to moisture absorbed in the first resin layer 304.

### Ninth Embodiment

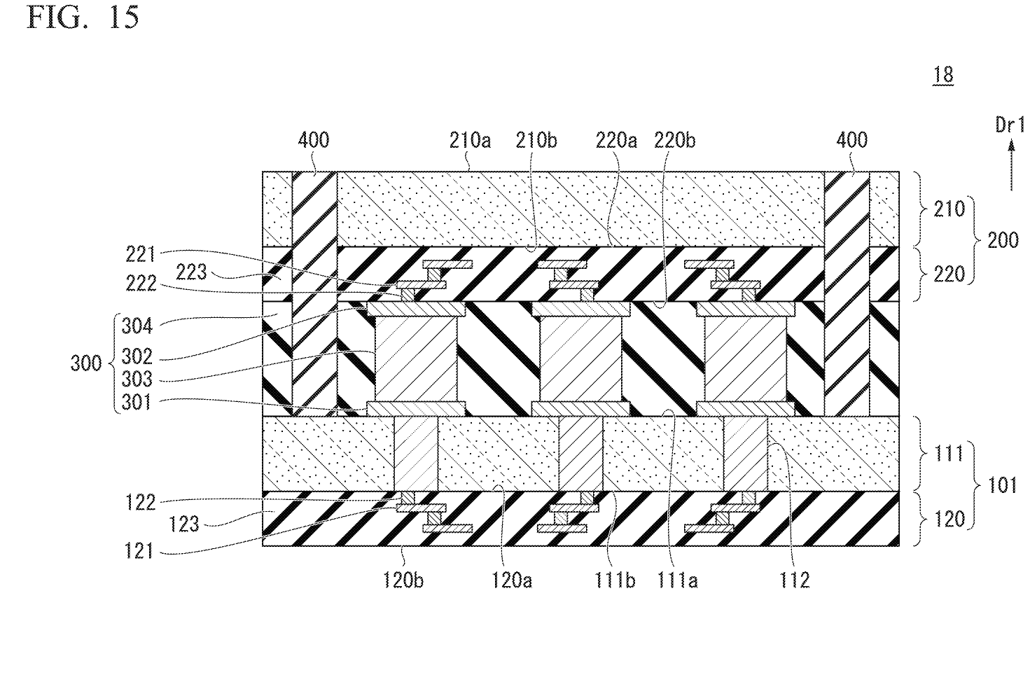

FIG. 15 shows a configuration of a semiconductor device 18 of a ninth embodiment of the present invention. In FIG. 15, a cross section of the semiconductor device 18 is shown. The semiconductor device 18 has a first substrate 101, the second substrate 200, the first connection portion 300, and the insulating layer 400. The first substrate 101 and the second substrate 200 are connected to each other via the first connection portion 300. The first substrate 101 and the second substrate 200 are stacked in the thickness direction Dr1 of the first substrate 101.

The differences between FIGS. 15 and 1 will be described. The first substrate 101 has a first semiconductor layer 111 and the first wire layer 120. The first semiconductor layer 111 and the first wire layer 120 are stacked in the thickness direction Dr1 of the first substrate 101. In addition, the first semiconductor layer 111 and the first wire layer 120 are in contact with each other.

The first semiconductor layer 111 is constituted of the same first semiconductor material as the first semiconductor material constituting the first semiconductor layer 110. The first semiconductor layer 111 has a surface 111a (first surface) and a surface 111b (second surface). The surface 111a of the first semiconductor layer 111 constitutes one of main surfaces of the first substrate 101. The surface 111a of the first semiconductor layer 111 faces the second substrate 200. The surface 111a of the first semiconductor layer 111 is in contact with the first connection portion 300. The surface 111b of the first semiconductor layer 111 is in contact with the first wire layer 120.

The first semiconductor layer 111 has first through-vias 112. In FIG. 15, there are a plurality of first through-vias 112, but the reference numeral is indicated for one first through-via 112 representatively. The first through-vias 112 penetrate the first semiconductor layer 111. The first through-vias 112 are in contact with the first vias 122 on the surface 120a of the first wire layer 120. Therefore, the first through-vias 112 are electrically connected to the first wires 121. The first through-vias 112 are in contact with the first pads 301 on the surface 111a of the first semiconductor layer 111.

The surface 120a of the first wire layer 120 faces the surface 111b of the first semiconductor layer 111. The surface 120a of the first wire layer 120 is in contact with the surface 111b of the first semiconductor layer 111. The surface 120b of the first wire layer 120 constitutes one of main surfaces of the first substrate 101.

At least one of the first semiconductor layer 111 and the first wire layer 120 may have a circuit element such as a transistor.

The first substrate 101 and the second substrate 200 are disposed such that the first semiconductor layer 111 and the second wire layer 220 face each other.

The first connection portions 300 are disposed between the first semiconductor layer 111 and the second wire layer 220. The first pads 301 are disposed on the surface 111a of the first semiconductor layer 111. The first pads 301 are in contact with the first through-vias 112 on the surface 111a of the first semiconductor layer 111. Therefore, the first pads 301 are electrically connected to the first wires 121.

As described above, the first semiconductor layer 111 has the first through-vias 112 which penetrate the first semiconductor layer 111. The first pads 301 are disposed on the surface 111a (first surface) of the first semiconductor layer 111 and are electrically connected to the first wires 121 by the first through-vias 112.

In regard to the matters other than those described above, the configuration shown in FIG. 15 is similar to the configuration shown in FIG. 1.

In place of the insulating layer 400, the insulating layer 401 shown in FIG. 4 may be disposed. In place of the insulating layer 400, the insulating layer 402 shown in FIG. 6 may be disposed. In place of the insulating layer 400, the insulating layer 403 and the metal layer 410 shown in FIG. 8 may be disposed. In place of the insulating layer 400, the insulating layer 404 and the metal layer 411 shown in FIG. 11 may be disposed. In place of the insulating layer 400, the insulating layer 405 and the metal layer 412 shown in FIG. 12 may be disposed.

As shown in FIG. 4, when the first pads 301 are disposed on the surface 120b (the fourth surface) of the first wire layer 120, the groove 901 on which the insulating layer 401 is disposed is open on the surface 120b of the first wire layer 120. Meanwhile, in the semiconductor device 18, when the insulating layer 401 shown in FIG. 4 is disposed, and the first pads 301 are disposed on the surface 111a (first surface) of the first semiconductor layer 111, the groove on which the insulating layer 401 is disposed is open on the surface 111a of the first semiconductor layer 111.

The insulating layer 400 may be disposed in an end portion of the semiconductor device 18. In place of the second substrate 200, the second substrate 201 shown in FIG. 14 may be disposed.

In the semiconductor device 10 of the first embodiment, the first pads 301 are disposed on the surface 120b of the first wire layer 120. In the semiconductor device 18 of the ninth embodiment, the first pads 301 are disposed on the surface 111a of the first semiconductor layer 111. Therefore, in the semiconductor device according to each of the aspects of the present invention, the configuration is acceptable as long as the first pads are disposed on the first surface of the first semiconductor layer or the fourth surface of the first wire layer.

The semiconductor device according to each of the aspects of the present invention does not need to have a configuration which corresponds to the first through-via 112.

According to the ninth embodiment, the semiconductor device 18 has the first substrate 101, the second substrate 200, the first pads 301, the second pads 302, the first micro-bumps 303, the first resin layer 304, and the insulating layer 400.

In the ninth embodiment, since the insulating layer 400 is disposed, moisture in the outside air which has infiltrated the first resin layer 304 is unlikely to reach the first micro-bump 303. As a result, in the semiconductor device 18, it is possible to reduce deformation of the first micro-bumps 303 caused due to moisture absorbed in the first resin layer 304.

### Tenth Embodiment

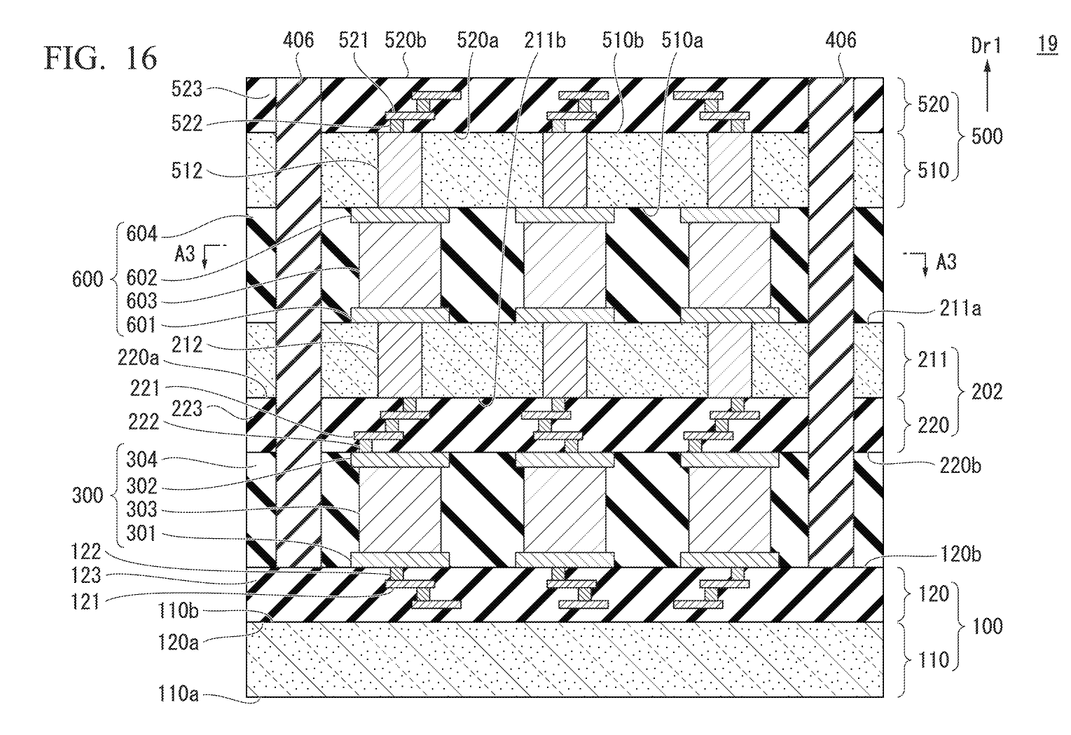

FIG. 16 shows a configuration of a semiconductor device 19 of a tenth embodiment of the present invention. In FIG. 16, a cross section of the semiconductor device 19 is shown. The semiconductor device 19 has the first substrate 100, a second substrate 202, the first connection portion 300, an insulating layer 406, a third substrate 500, and a second connection portion 600. The first substrate 100 and the second substrate 202 are connected to each other via the first connection portion 300. The first substrate 100 and the second substrate 202 are stacked in the thickness direction Dr1 of the first substrate 100. The second substrate 202 and the third substrate 500 are connected via the second connection portion 600. The second substrate 202 and the third substrate 500 are stacked in the thickness direction Dr1 of the first substrate 100.

The differences between FIG. 16 and FIG. 1 or 14 will be described. The second substrate 202 has the second semiconductor layer 211 and the second wire layer 220. In FIG. 16, the disposition of the second semiconductor layer 211 and the second wire layer 220 is different from the disposition of the second semiconductor layer 211 and the second wire layer 220 in FIG. 14.

The surface 211a of the second semiconductor layer 211 faces the third substrate 500. The surface 211a of the second semiconductor layer 211 is in contact with the second connection portion 600. The surface 211b of the second semiconductor layer 211 is in contact with the second wire layer 220.

The first substrate 100 and the second substrate 202 are disposed such that the first wire layer 120 and the second wire layer 220 face each other.

The third substrate 500 has a third semiconductor layer 510 and a third wire layer 520. The third semiconductor layer 510 and the third wire layer 520 are stacked in the thickness direction Dr1 of the first substrate 100. In addition, the third semiconductor layer 510 and the third wire layer 520 are in contact with each other.

The third semiconductor layer 510 is constituted of a third semiconductor material. The third semiconductor material is the same as the first semiconductor material constituting the first semiconductor layer 110, or the second semiconductor material constituting the second semiconductor layer 210. Alternatively, the third semiconductor material is different from the first semiconductor material and the second semiconductor material. For example, the third semiconductor material is silicon (Si). The third semiconductor layer 510 has a surface 510a (ninth surface) and a surface 510b (tenth surface). The surface 510a of the third semiconductor layer 510 constitutes one of main surfaces of the third substrate 500. The surface 510a of the third semiconductor layer 510 faces the second substrate 202. The surface 510a of the third semiconductor layer 510 is in contact with the second connection portion 600. The surface 510b of the third semiconductor layer 510 is in contact with the third wire layer 520.

The third semiconductor layer 510 has third through-vias 512. In FIG. 16, there are a plurality of third through-vias 512, but the reference numeral is indicated for one third through-via 512 representatively. The third through-vias 512 penetrate the third semiconductor layer 510. The third through-vias 512 are in contact with third vias 522 on a surface 520a of the third wire layer 520. Therefore, the third through-vias 512 are electrically connected to third wires 521. The third through-vias 512 are in contact with fourth pads 602 on the surface 510a of the third semiconductor layer 510.

The third wire layer 520 has the third wires 521, the third vias 522, and a third interlayer insulating film 523. In FIG. 16, there are a plurality of third wires 521, but the reference numeral is indicated for one third wire 521 representatively. In FIG. 16, there are a plurality of third vias 522, but the reference numeral is indicated for one third via 522 representatively.

The third wire layer 520 has the surface 520a (eleventh surface) and a surface 520b (twelfth surface). The surface 520a of the third wire layer 520 faces the surface 510b of the third semiconductor layer 510. The surface 520a of the third wire layer 520 is in contact with the surface 510b of the third semiconductor layer 510. The surface 520b of the third wire layer 520 constitutes one of main surfaces of the third substrate 500.

The third wires 521 and the third vias 522 are constituted of a third conductive material. The third conductive material is the same as the first conductive material constituting the first wires 121 and the first vias 122, or the second conductive material constituting the second wires 221 and the second vias 222. Alternatively, the third conductive material is different from the first conductive material and the second conductive material. For example, the third conductive material is metal such as aluminum (Al) and copper (Cu). The third wires 521 and the third vias 522 may be constituted of different conductive materials. Each of the third wires 521 is a thin film in which a wire pattern is formed. The third wires 521 transmit signals. Only one layer of the third wires 521 may be disposed, or a plurality of layers of the third wires 521 may be disposed. In the example shown in FIG. 16, two layers of the third wires 521 are disposed.

The third vias 522 connect two different layers of the third wires 521. In the third wire layer 520, portions other than the third wires 521 and the third vias 522 are formed by the third interlayer insulating film 523. The third interlayer insulating film 523 is constituted of a third insulating material. The third insulating material is the same as the first insulating material constituting the first interlayer insulating film 123 or the second insulating material constituting the second interlayer insulating film 223. Alternatively, the third insulating material is different from the first insulating material and the second insulating material. For example, the third insulating material is silicon dioxide (SiO2).

At least one of the third semiconductor layer 510 and the third wire layer 520 may have a circuit element such as a transistor.

As described above, the third substrate 500 has the third semiconductor layer 510 and the third wire layer 520. The third semiconductor layer 510 has the surface 510a (ninth surface) and the surface 510b (tenth surface) and contains the third semiconductor material. The third wire layer 520 has the surface 520a (eleventh surface), the surface 520b (twelfth surface), and the third wires 521. The surface 520a faces the surface 510b of the third semiconductor layer 510.

The second substrate 202 and the third substrate 500 are disposed such that the second semiconductor layer 211 and the third semiconductor layer 510 face each other.

The second connection portion 600 is disposed between the second semiconductor layer 211 and the third semiconductor layer 510. The second connection portion 600 electrically connects the second wires 221 and the third wires 521 with each other. The second connection portion 600 has a third pad 601, a fourth pad 602, a second micro-bump 603, and a second resin layer 604. In FIG. 16, there are a plurality of third pads 601, but the reference numeral is indicated for one third pad 601 representatively. In FIG. 16, there are a plurality of fourth pads 602, but the reference numeral is indicated for one fourth pad 602 representatively. In FIG. 16, there are a plurality of second micro-bumps 603, but the reference numeral is indicated for one second micro-bump 603 representatively.

The third pads 601 are constituted of a conductive material. The conductive material constituting the third pads 601 is the same as any one of the first conductive material constituting the first wires 121 and the first vias 122, the second conductive material constituting the second wires 221 and the second vias 222, and the third conductive material constituting the third wires 521 and the third vias 522. Alternatively, the conductive material constituting the third pads 601 is different from the first conductive material, the second conductive material, and the third conductive material. For example, the conductive material constituting the third pads 601 is metal such as gold (Au), copper (Cu), and nickel (Ni).

The third pads 601 are thin films. The third pads 601 are disposed on the surface 211a of the second semiconductor layer 211. The third pads 601 are in contact with the second through-vias 212 on the surface 211a of the second semiconductor layer 211. Therefore, the third pads 601 are electrically connected to the second wires 221.

The fourth pads 602 are constituted of a conductive material. The conductive material constituting the fourth pads 602 is the same as any one of the first conductive material constituting the first wires 121 and the first vias 122, the second conductive material constituting the second wires 221 and the second vias 222, and the third conductive material constituting the third wires 521 and the third vias 522. Alternatively, the conductive material constituting the fourth pads 602 is different from the first conductive material, the second conductive material, and the third conductive material. For example, the conductive material constituting the fourth pads 602 is metal such as gold (Au), copper (Cu), and nickel (Ni).

The fourth pads 602 are thin films. The fourth pads 602 are disposed on the surface 510a of the third semiconductor layer 510. The fourth pads 602 are in contact with the third through-vias 512 on the surface 510a of the third semiconductor layer 510. Therefore, the fourth pads 602 are electrically connected to the third wires 521.

The second micro-bumps 603 are constituted of a conductive material. The conductive material constituting the second micro-bumps 603 is the same as any one of the first conductive material constituting the first wires 121 and the first vias 122, the second conductive material constituting the second wires 221 and the second vias 222, and the third conductive material constituting the third wires 521 and the third vias 522. Alternatively, the conductive material constituting the second micro-bumps 603 is different from the first conductive material, the second conductive material, and the third conductive material. For example, the conductive material constituting the second micro-bumps 603 is metal such as gold (Au), copper (Cu), and nickel (Ni).

The second micro-bumps 603 are columnar structures. The second micro-bumps 603 may be spherical structures. The second micro-bumps 603 are disposed between the third pads 601 and the fourth pads 602 and are electrically connected to the third pads 601 and the fourth pads 602. Due to the configuration described above, the third pads 601, the fourth pads 602, and the second micro-bumps 603 are electrically connected to the second wires 221 and the third wires 521 and transmit signals between the second substrate 202 and the third substrate 500.

The second resin layer 604 is disposed between the second semiconductor layer 211 and the third semiconductor layer 510. The second resin layer 604 is constituted of a second resin material. The second resin material is the same as the first resin material constituting the first resin layer 304. Alternatively, the second resin material is different from the first resin material. For example, the second resin material is underfill resin. The second resin layer 604 covers the outer surfaces of the third pads 601, the fourth pads 602, and the second micro-bumps 603.

As described above, the third pads 601 are disposed on the surface 211a (fifth surface) of the second semiconductor layer 211 and are electrically connected to the second wires 221. The fourth pads 602 are disposed on the surface 510a (ninth surface) of the third semiconductor layer 510 and are electrically connected to the third wires 521. The second micro-bumps 603 are disposed between the second substrate 202 and the third substrate 500 and are electrically connected to the third pads 601 and the fourth pads 602. The second resin layer 604 is disposed between the second substrate 202 and the third substrate 500 and is in contact with the third pads 601, the fourth pads 602, and the second micro-bumps 603. The second resin layer 604 contains the second resin material.

The insulating layer 406 penetrates the third substrate 500, the second substrate 200, and the first resin layer 304. The insulating layer 406 is constituted of an insulating material similar to the insulating material constituting the insulating layer 400. The insulating layer 406 contains the insulating material having hygroscopic properties lower than the hygroscopic properties of both of the first resin layer 304 and the second resin layer 604. The coefficient of moisture absorption of the insulating layer 406 is smaller than a coefficient of moisture absorption of the first resin layer 304 and a coefficient of moisture absorption of the second resin layer 604.

In regard to the matters other than those described above, the configuration shown in FIG. 16 is similar to the configuration shown in FIG. 1 or 14.

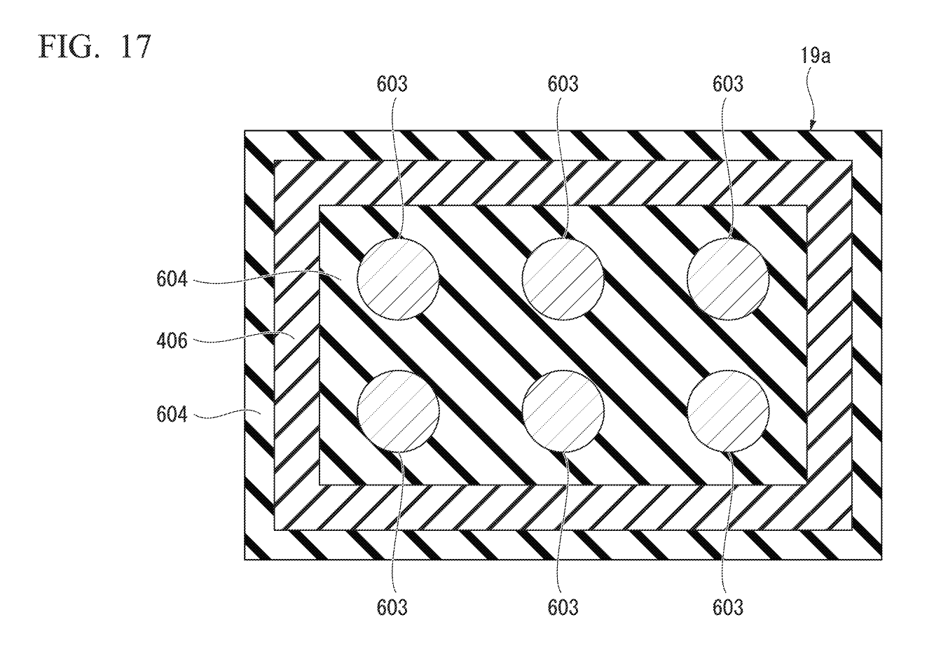

FIG. 17 shows a second cross section 19a of the semiconductor device 19 at a position A3 in FIG. 16. The second cross section 19a passes through the second micro-bumps 603, the second resin layer 604, and the insulating layer 406 and is parallel to the surface 110a of the first semiconductor layer 110.

As shown in FIG. 17, the semiconductor device 19 has the plurality of second micro-bumps 603. The plurality of second micro-bumps 603 are disposed in a circuit forming region including a central portion in the second cross section 19a. For example, the plurality of second micro-bumps 603 are disposed in a matrix. A cross section of the second micro-bump 603 has a circular shape. A cross section of the second micro-bump 603 may have a polygonal shape.

In the second cross section 19a, the insulating layer 406 is disposed such that the insulating layer 406 surrounds the plurality of second micro-bumps 603. That is, in the second cross section 19a, the plurality of second micro-bumps 603 are surrounded by the insulating layer 406. In the second cross section 19a, there is no cut end or gap in the insulating layer 406.

As described above, the insulating layer 406 contains an insulating material having hygroscopic properties lower than the hygroscopic properties of both of the first resin layer 304 and the second resin layer 604. The insulating layer 406 penetrates the third substrate 500, the second substrate 200, and the first resin layer 304. The insulating layer 406 surrounds the second micro-bumps 603 in the second cross section 19a which passes through the second micro-bumps 603, the second resin layer 604, and the insulating layer 406 and is parallel to the surface 110a (first surface) of the first semiconductor layer 110.

Similarly, in a cross section which passes through the third pads 601, the second resin layer 604, and the insulating layer 406 and is parallel to the surface 110a of the first semiconductor layer 110, the insulating layer 406 surrounds the second micro-bumps 603. Moreover, the insulating layer 406 surrounds the second micro-bumps 603 in a cross section which passes through the fourth pads 602, the second resin layer 604, and the insulating layer 406 and is parallel to the surface 110a of the first semiconductor layer 110.

The second resin layer 604 is exposed to the outside air at the tip end of the semiconductor device 19. That is, the second resin layer 604 comes in touch with the outside air at the tip end of the semiconductor device 19, so that moisture in the outside air infiltrates the second resin layer 604. Due to the low hygroscopic properties of the insulating layer 406, moisture is unlikely to infiltrate the insulating layer 406. In addition, since the insulating layer 406 penetrates the second resin layer 604, the insulating layer 406 blocks a pathway from the tip end to the second micro-bumps 603. Therefore, moisture in the outside air which has infiltrated the second resin layer 604 is unlikely to reach the second micro-bumps 603. As a result, in the semiconductor device 19, it is possible to reduce deformation of the second micro-bumps 603 caused due to moisture absorbed in the second resin layer 604.

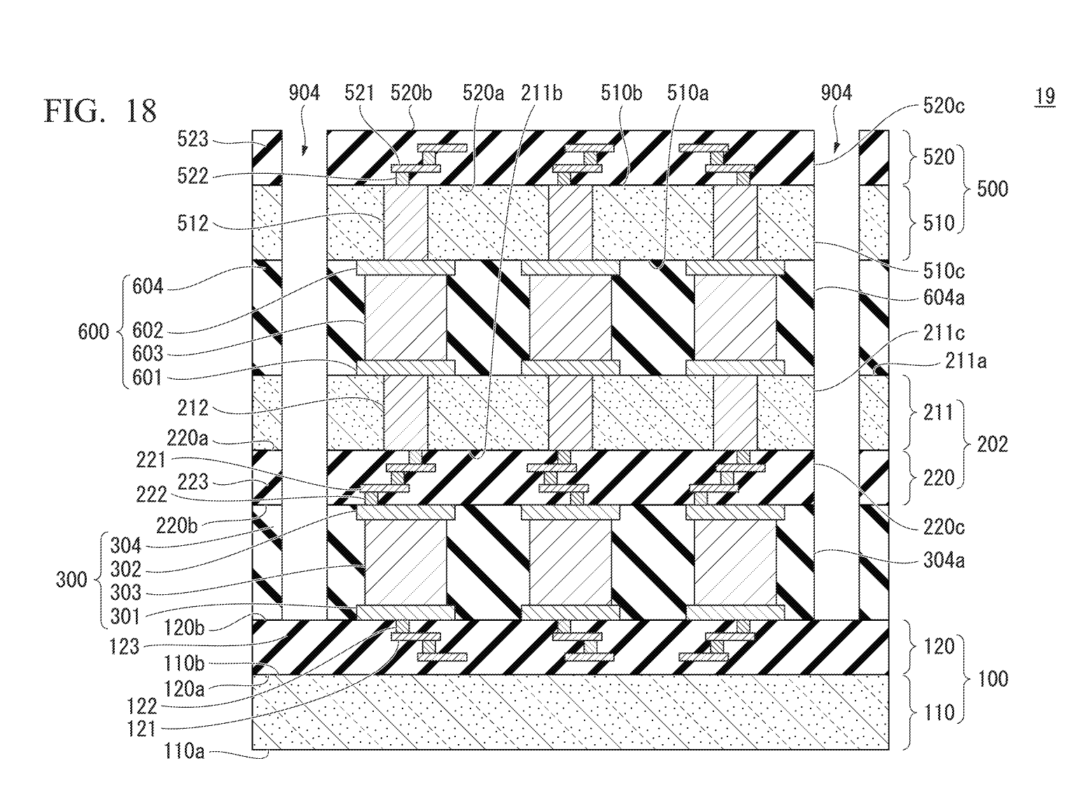

A method of manufacturing the insulating layer 406 will be described. FIG. 18 shows the semiconductor device 19 before the insulating layer 406 is formed therein. In FIG. 18, a cross section of the semiconductor device 19 is shown.

In a step of manufacturing the insulating layer 406, the third wire layer 520, the third semiconductor layer 510, the second resin layer 604, the second semiconductor layer 211, the second wire layer 220, and the first resin layer 304 are dug downward in that order from the surface 520b of the third wire layer 520. Accordingly, the surface 120b of the first wire layer 120 is exposed and a groove 904 is then formed. The semiconductor device 19 has the groove 904. The groove 904 is formed throughout the third wire layer 520, the third semiconductor layer 510, the second resin layer 604, the second semiconductor layer 211, the second wire layer 220, and the first resin layer 304.

The groove 904 includes a side surface 520c of the third wire layer 520, a side surface 510c of the third semiconductor layer 510, a side surface 604a of the second resin layer 604, a side surface 211c of the second semiconductor layer 211, the side surface 220c of the second wire layer 220, the side surface 304a of the first resin layer 304, and the surface 120b of the first wire layer 120. The insulating layer 406 is formed by filling the groove 904 with an insulating material. That is, the insulating layer 406 is disposed in the groove 904.

The insulating layer 406 may penetrate the first wire layer 120. A metal layer may be disposed inside the insulating layer 406. The insulating layer 406 may be disposed in an end portion of the semiconductor device 19. In place of the first substrate 100, the first substrate 101 shown in FIG. 15 may be disposed.

As shown in FIG. 16, the second pads 302 are disposed on the surface 220b (eighth surface) of the second wire layer 220, and the third pads 601 are disposed on the surface 211a (fifth surface) of the second semiconductor layer 211. The second semiconductor layer 211 may be in contact with the first connection portion 300, and the second wire layer 220 may be in contact with the second connection portion 600. In this case, the second pads 302 are disposed on the surface 211a (fifth surface) of the second semiconductor layer 211, and the third pads 601 are disposed on the surface 220b (eighth surface) of the second wire layer 220. Therefore, in the semiconductor device according to each of the aspects of the present invention, the configuration is acceptable as long as the third pads are disposed on the eighth surface of the second wire layer or the fifth surface of the second semiconductor layer. When the second pads are disposed on the fifth surface of the second semiconductor layer, the third pads are disposed on the eighth surface of the second wire layer. When the second pads are disposed on the eighth surface of the second wire layer, the third pads are disposed on the fifth surface of the second semiconductor layer.

As shown in FIG. 16, the fourth pads 602 are disposed on the surface 510a (ninth surface) of the third semiconductor layer 510. The positional relationship between the third semiconductor layer 510 and the third wire layer 520 may be reversed. That is, the third wire layer 520 may be in contact with the second connection portion 600. In this case, the fourth pads 602 are disposed on the surface 520b (twelfth surface) of the third wire layer 520. Therefore, in the semiconductor device according to each of the aspects of the present invention, the configuration is acceptable as long as the fourth pads are disposed on the ninth surface of the third semiconductor layer or the twelfth surface of the third wire layer.

The semiconductor device according to each of the aspects of the present invention does not need to have a configuration which corresponds to at least one of the third through-via 512 and the third via 522.

The semiconductor device according to each of the aspects of the present invention may have four or more substrates and have three or more connection portions. When a semiconductor device has four or more substrates, the semiconductor device includes a structure similar to any one of the structures of the semiconductor device 10, the semiconductor device 11, the semiconductor device 12, the semiconductor device 13, the semiconductor device 14, the semiconductor device 15, the semiconductor device 16, the semiconductor device 17, and the semiconductor device 18. When a semiconductor device has four or more substrates, the semiconductor device may include a structure similar to that of the semiconductor device 19.

According to the tenth embodiment, the semiconductor device 19 has the first substrate 100, the second substrate 202, the first pads 301, the second pads 302, the first micro-bumps 303, the first resin layer 304, and the insulating layer 406. Moreover, the semiconductor device 19 has the third substrate 500, the third pads 601, the fourth pads 602, the second micro-bumps 603, and the second resin layer 604.

In the tenth embodiment, since the insulating layer 406 is disposed, moisture in the outside air which has infiltrated the first resin layer 304 is unlikely to reach the first micro-bump 303. As a result, in the semiconductor device 19, it is possible to reduce deformation of the first micro-bumps 303 caused due to moisture absorbed in the first resin layer 304.

In the tenth embodiment, since the insulating layer 406 is disposed, moisture in the outside air which has infiltrated the second resin layer 604 is unlikely to reach the second micro-bumps 603. As a result, in the semiconductor device 19, it is possible to reduce deformation of the second micro-bumps 603 caused due to moisture absorbed in the second resin layer 604.

### Eleventh Embodiment

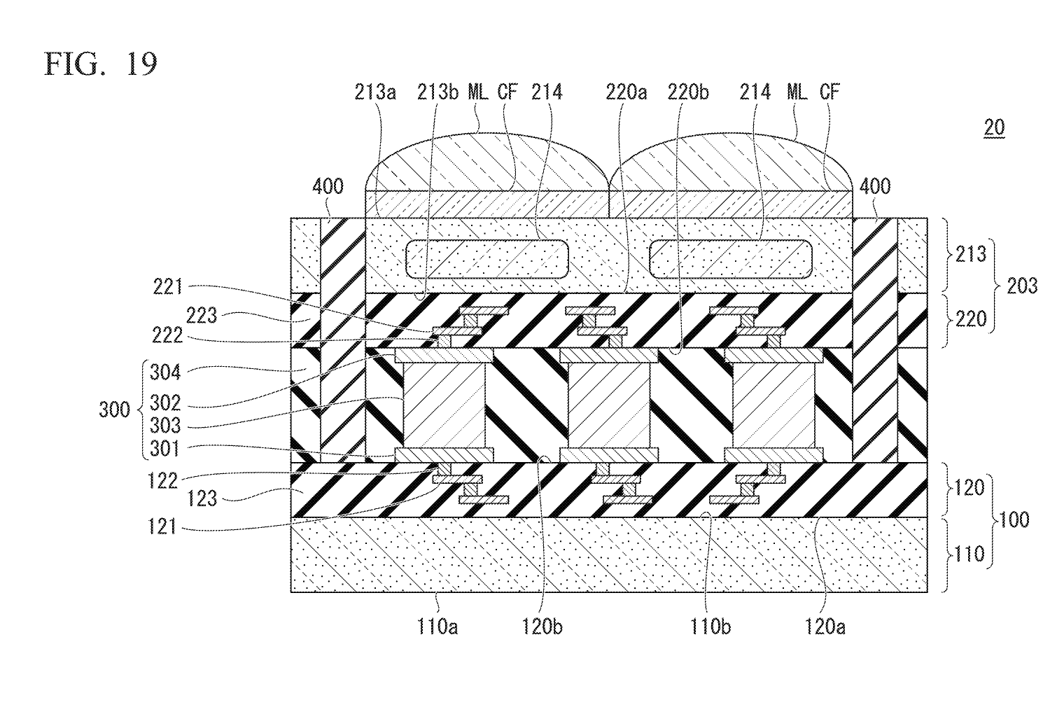

FIG. 19 shows a configuration of a semiconductor device 20 of an eleventh embodiment of the present invention. In FIG. 19, a cross section of the semiconductor device 20 is shown. The semiconductor device 20 has the first substrate 100, a second substrate 203, the first connection portion 300, the insulating layer 400, a microlens ML, and a color filter CF. The first substrate 100 and the second substrate 203 are connected to each other via the first connection portion 300. The first substrate 100 and the second substrate 203 are stacked in the thickness direction Dr1 of the first substrate 100. The semiconductor device 20 is a solid-state imaging device.

The differences between FIGS. 19 and 1 will be described. The second substrate 203 has a second semiconductor layer 213 and the second wire layer 220. The second semiconductor layer 213 and the second wire layer 220 are stacked in the thickness direction Dr1 of the first substrate 100. In addition, the second semiconductor layer 213 and the second wire layer 220 are in contact with each other.

The second semiconductor layer 213 is constituted of the same second semiconductor material as the second semiconductor material constituting the second semiconductor layer 210. The second semiconductor layer 213 has a surface 213a (fifth surface) and a surface 213b (sixth surface). The surface 213a of the second semiconductor layer 213 constitutes one of main surfaces of the second substrate 203. The surface 213a of the second semiconductor layer 213 is in contact with the color filter CF. The surface 213b of the second semiconductor layer 213 is in contact with the second wire layer 220.

The second semiconductor layer 213 has a photoelectric conversion unit 214. For example, the photoelectric conversion unit 214 is constituted of a semiconductor material of which the impurity concentration is different from that of the second semiconductor material constituting the second semiconductor layer 213.

The color filter CF is disposed on the surface 213a of the second semiconductor layer 213. The microlens ML is disposed on the color filter CF.

Light from a photographic subject, which has passed through an imaging lens disposed optically ahead of the semiconductor device 20, is incident on the microlens ML. The microlens ML images the light which has been transmitted through the imaging lens. The color filter CF allows light having a wavelength corresponding to a predetermined color to be transmitted.

Light which has been transmitted through the microlens ML and the color filter CF is incident on the second semiconductor layer 213. The light incident on the second semiconductor layer 213 travels inside the second semiconductor layer 213 and is then incident on the photoelectric conversion unit 214. The photoelectric conversion unit 214 converts the incident light into a signal.

In regard to the matters other than those described above, the configuration shown in FIG. 19 is similar to the configuration shown in FIG. 1.

In the eleventh embodiment, since the insulating layer 400 is disposed, moisture in the outside air which has infiltrated the first resin layer 304 is unlikely to reach the first micro-bump 303. As a result, in the semiconductor device 20, it is possible to reduce deformation of the first micro-bumps 303 caused due to moisture absorbed in the first resin layer 304.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor device, comprising:
a first substrate having a first semiconductor layer which has a first surface and a second surface and contains a first semiconductor material, and a first wire layer which has a third surface, a fourth surface, and a first wire, the third surface facing the second surface;
a second substrate having a second semiconductor layer which has a fifth surface and a sixth surface and contains a second semiconductor material, and a second wire layer which has a seventh surface, an eighth surface, and a second wire, the seventh surface facing the sixth surface;
a first pad that is disposed on the first surface or the fourth surface and is electrically connected to the first wire;
a second pad that is disposed on the fifth surface or the eighth surface and is electrically connected to the second wire;
a first micro-bump that is disposed between the first substrate and the second substrate and is electrically connected to the first pad and the second pad;
a first resin layer that is disposed between the first substrate and the second substrate, is in contact with the first pad, the second pad, and the first micro-bump, and contains a first resin material; and
an insulating layer that contains an insulating material having hygroscopic properties lower than hygroscopic properties of the first resin layer,
wherein the insulating layer penetrates the second substrate and the first resin layer, and
the insulating layer surrounds the first micro-bump in a first cross section which passes through the first micro-bump, the first resin layer, and the insulating layer and is parallel to the first surface.

2. The semiconductor device according to claim 1,
wherein the first substrate has a groove,
the groove is open on the first surface when the first pad is disposed on the first surface,
the groove is open on the fourth surface when the first pad is disposed on the fourth surface, and
the insulating layer is also disposed in the groove.

3. The semiconductor device according to claim 1, further comprising:
a metal layer that contains a metal material,
wherein the metal layer penetrates the second substrate and is disposed inside the first resin layer,
the metal layer surrounds the first micro-bump in the first cross section, and
the insulating layer surrounds the metal layer in the first cross section.

4. The semiconductor device according to claim 1,
wherein the insulating layer includes an end portion of the semiconductor device.

5. The semiconductor device according to claim 1,
wherein the second pad is disposed on the eighth surface.

6. The semiconductor device according to claim 1,
wherein the second semiconductor layer has a through-via which penetrates the second semiconductor layer, and
the second pad is disposed on the fifth surface and is electrically connected to the second wire by the through-via.

7. The semiconductor device according to claim 1, further comprising:
a third substrate having a third semiconductor layer which has a ninth surface and a tenth surface and contains a third semiconductor material, and a third wire layer which has an eleventh surface, a twelfth surface, and a third wire, the eleventh surface facing the tenth surface;
a third pad that is disposed on the eighth surface or the fifth surface and is electrically connected to the second wire;
a fourth pad that is disposed on the ninth surface or the twelfth surface and is electrically connected to the third wire;
a second micro-bump that is disposed between the second substrate and the third substrate and is electrically connected to the third pad and the fourth pad; and
a second resin layer that is disposed between the second substrate and the third substrate, is in contact with the third pad, the fourth pad, and the second micro-bump, and contains a second resin material,
wherein the insulating layer contains an insulating material having hygroscopic properties lower than hygroscopic properties of both of the first resin layer and the second resin layer,
the insulating layer also penetrates the third substrate, and
the insulating layer surrounds the second micro-bump in a second cross section which passes through the second micro-bump, the second resin layer, and the insulating layer and is parallel to the first surface.
